(19) United States
(12) Patent Application Publication
(10) Pub. No.: US 2025/0040216 A1
(43) Pub. Date: Jan. 30, 2025

(54) SEMICONDUCTOR DEVICE

(71) Applicant: Samsung Electronics Co., Ltd., Suwon-si (KR)

(72) Inventors: Sungil Park, Suwon-si (KR); Jaehyun Park, Suwon-si (KR)

(21) Appl. No.: 18/659,064

(22) Filed: May 9, 2024

(30) Foreign Application Priority Data
Jul. 28, 2023 (KR) 10-2023-0099103

(51) Int. Cl. H01L 29/66; H01L 29/06; H01L 29/08; H01L 29/423; H01L 29/775; H01L 29/786

(52) U.S. Cl. CPC H01L 29/66545; H01L 29/0673; H01L 29/0847; H01L 29/42392; H01L 29/775; H01L 29/78696

(57) ABSTRACT

A semiconductor device includes a semiconductor stack body having a first surface and a second surface, and including semiconductor layers having different compositions stacked therein, wherein the semiconductor stack body has a recess in the second surface and a through-hole penetrating through the semiconductor stack body; a plurality of inactive gate structures disposed on a second surface of the semiconductor stack body; a first conductivity-type epitaxial pattern disposed in the through-hole and connected to a first impurity region in the semiconductor stack body; a second conductivity-type epitaxial pattern disposed in the recess and connected to a second impurity region in the semiconductor stack body; a first contact connected to the first conductivity-type epitaxial pattern; and a second contact connected to the second conductivity-type epitaxial pattern.

### CROSS-REFERENCE TO RELATED APPLICATION(S)

This application claims benefit of priority under 35 U.S.C. § 119 to Korean Patent Application No. 10-2023-0099103, filed on Jul. 28, 2023, in the Korean Intellectual Property Office, the entire contents of which are incorporated herein by reference.

### BACKGROUND

Example embodiments of the present disclosure relate to a semiconductor device.

As demands for high performance, speed, and/or multifunctionality in a semiconductor device have increased, integration density of a semiconductor device has also increased. To overcome limitations in operation properties due to reductions in a size of a planar metal oxide semiconductor field effect transistor (MOSFET), there have been effects to develop a semiconductor device including a FinFET including a fin-shaped channel and a gate-all-around type field effect transistor including nanosheets surrounded by a gate.

### SUMMARY

An example embodiment of the present disclosure is to provide a semiconductor device having improved electrical properties and reliability.

According to an example embodiment of the present disclosure, a semiconductor device includes a semiconductor stack body having a first surface and a second surface opposite to each other, including semiconductor layers having different compositions stacked therein, and including at least one of a first conductivity-type impurity region and a second conductivity-type impurity region, wherein the semiconductor stack body has a recess formed in the second surface and a through-hole penetrating through the semiconductor stack body; a plurality of inactive gate structures disposed and spaced apart from each other on the second surface of the semiconductor stack body, wherein each of the recess and the through-hole is disposed between the plurality of inactive gate structures; a first conductivity-type epitaxial pattern disposed in the through-hole and connected to the semiconductor stack body; a second conductivity-type epitaxial pattern disposed in the recess and connected to the semiconductor stack body; a first gap-fill insulating layer disposed on the first conductivity-type epitaxial pattern in the through-hole adjacent to the second surface of the semiconductor stack body; a second gap-fill insulating layer disposed between the plurality of inactive gate structures on the second surface of the semiconductor stack body; a first contact penetrating through the first gap-fill insulating layer and connected to the first conductivity-type epitaxial pattern; and a second contact penetrating through the second gap-fill insulating layer and connected to the second conductivity-type epitaxial pattern.

According to an example embodiment of the present disclosure, a semiconductor device includes a semiconductor stack body including an upper stack body having an intermediate semiconductor layer, and first upper semiconductor layers and second upper semiconductor layers stacked alternately on an upper surface of the intermediate semiconductor layer, a lower stack body having first lower semiconductor layers and second lower semiconductor layers stacked alternately on a lower surface of the intermediate semiconductor layer, and a first conductivity-type impurity region and a second conductivity-type impurity region disposed horizontally; a plurality of inactive gate structures arranged at a pitch on a lower surface of the semiconductor stack body; at least one recess disposed between at least one pair of adjacent inactive gate structures among the plurality of inactive gate structures and penetrating through the lower stack body from a lower surface of the semiconductor stack body; at least one through-hole disposed between at least one pair of adjacent inactive gate structures among the plurality of inactive gate structures and penetrating through the semiconductor stack body; at least one first conductivity-type epitaxial pattern disposed in the at least one through-hole and connected to the upper stack body of the semiconductor stack body; and at least one second conductivity-type epitaxial pattern disposed in the at least one recess and connected to the lower stack body of the semiconductor stack body.

According to an example embodiment of the present disclosure, a semiconductor device includes a first device region and a second device region disposed horizontally, wherein the first device region includes a channel structure including an insulating isolation pattern, first semiconductor patterns vertically stacked and spaced apart from each other on an upper surface of the insulating isolation pattern, and second semiconductor patterns vertically stacked and spaced apart from each other on a lower surface of the insulating isolation pattern; a pair of first source/drain patterns disposed on both sides of the channel structure in the first direction and connected to both sides of the first semiconductor patterns, respectively; a pair of second source/drain patterns disposed on both sides of the channel structure and connected to both sides of the second semiconductor patterns, respectively; a first gate structure extending in a second direction intersecting the first direction and surrounding the first semiconductor patterns; and a second gate structure intersecting a lower surface of the channel structure, extending in the second direction and surrounding the second semiconductor patterns, and wherein the second device region includes a semiconductor stack body disposed on a level corresponding to a level of the channel structure, and including an upper stack body having first upper semiconductor layers and second upper semiconductor layers alternately stacked on an upper surface of the intermediate semiconductor layer, and a lower stack body having first lower semiconductor layers and second lower semiconductor layers stacked alternately on a lower surface of the intermediate semiconductor layer, wherein the semiconductor stack body includes a first conductivity-type impurity region and a second conductivity-type impurity region disposed in a horizontal direction; a plurality of inactive gate electrodes arranged on a lower surface of the semiconductor stack body; a first conductivity-type epitaxial pattern disposed in a through-hole penetrating through the semiconductor stack body between adjacent inactive gate structures among the plurality of inactive gate structures, and connected to the upper stack body; and a second conductivity-type epitaxial pattern disposed in a recess formed on a lower surface of the semiconductor stack body between other adjacent inactive gate structures among the plurality of inactive gate structures, and connected to the lower stack body.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to an example embodiment of the present disclosure;

FIGS. 2A to 2C are cross-sectional diagrams illustrating a first device region A of a semiconductor device in FIG. 1 taken along lines I-I′, II1-II1′, and II2-II2′, respectively;

FIGS. 3A and 3B are cross-sectional diagrams illustrating a second device region B of a semiconductor device in FIG. 1 taken along lines III-III′, and IV-IV′, respectively;

FIG. 4A is a cross-sectional diagram illustrating a first device region of a semiconductor device taken along line I-I′ according to an example embodiment of the present disclosure;

FIG. 4B is a cross-sectional diagram illustrating a second device region of a semiconductor device taken along line III-III′ according to an example embodiment of the present disclosure;

FIGS. 5A and 5B are a plan diagram and a lateral cross-sectional diagram, respectively, illustrating a semiconductor device (e.g., a circuit device) according to an example embodiment of the present disclosure;

FIGS. 6A and 6B are cross-sectional diagrams illustrating a semiconductor device (e.g., a circuit device) according to an example embodiment of the present disclosure;

FIGS. 7A and 7B are a plan diagram and a lateral cross-sectional diagram, respectively, illustrating a semiconductor device (e.g., a circuit device) according to an example embodiment of the present disclosure;

FIG. 8 is a lateral cross-sectional diagram illustrating a semiconductor device (e.g., circuit device) according to an example embodiment of the present disclosure;

FIGS. 9A and 9B are a plan diagram and a lateral cross-sectional diagram, respectively, illustrating a semiconductor device (e.g., capacitor) according to an example embodiment of the present disclosure;

FIG. 10 is a lateral cross-sectional diagram illustrating a semiconductor device (e.g., capacitor) according to an example embodiment of the present disclosure;

FIGS. 11A to 11I are cross-sectional diagrams illustrating a portion of processes of a method of manufacturing a semiconductor device according to an example embodiment of the present disclosure; and

FIGS. 12A to 12G are cross-sectional diagrams illustrating the another portion of processes of a method of manufacturing a semiconductor device according to an example embodiment of the present disclosure.

### DETAILED DESCRIPTION

Hereinafter, embodiments of the present disclosure will be described as follows with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below.

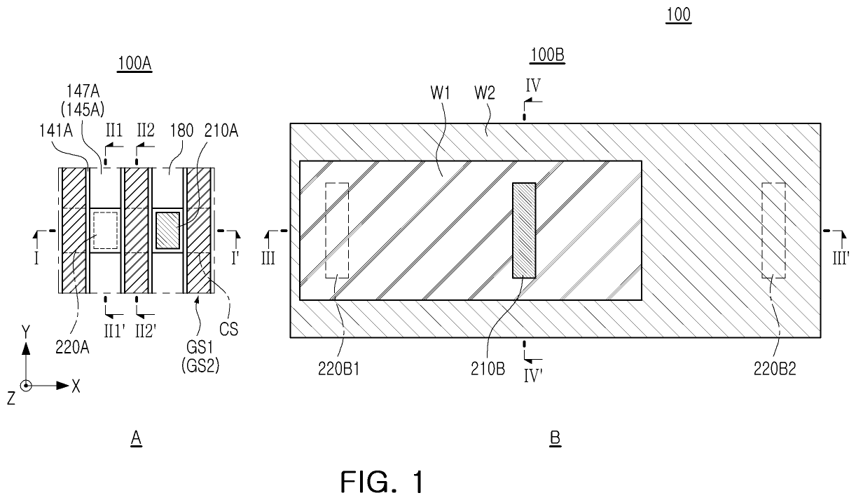

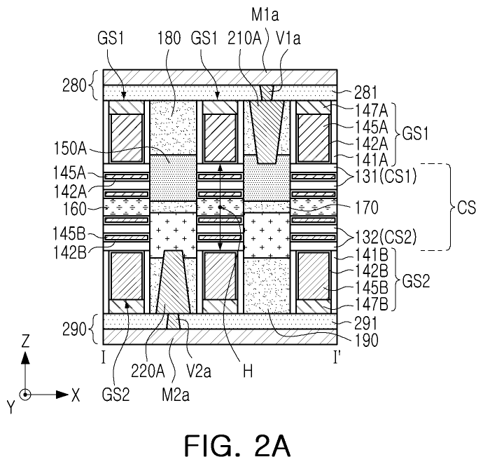

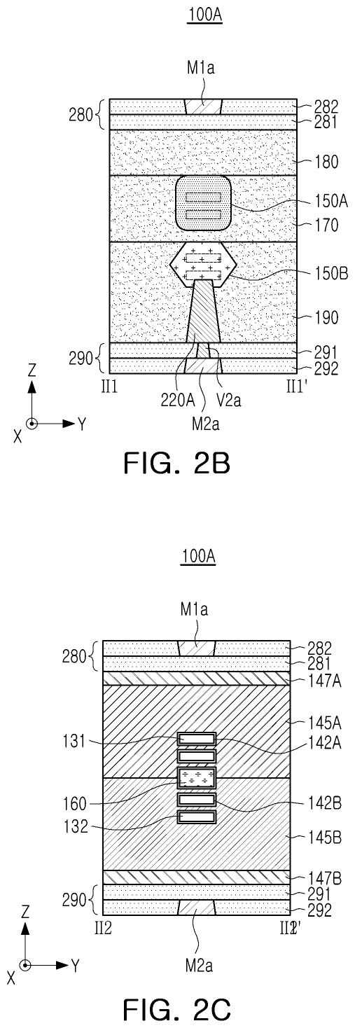

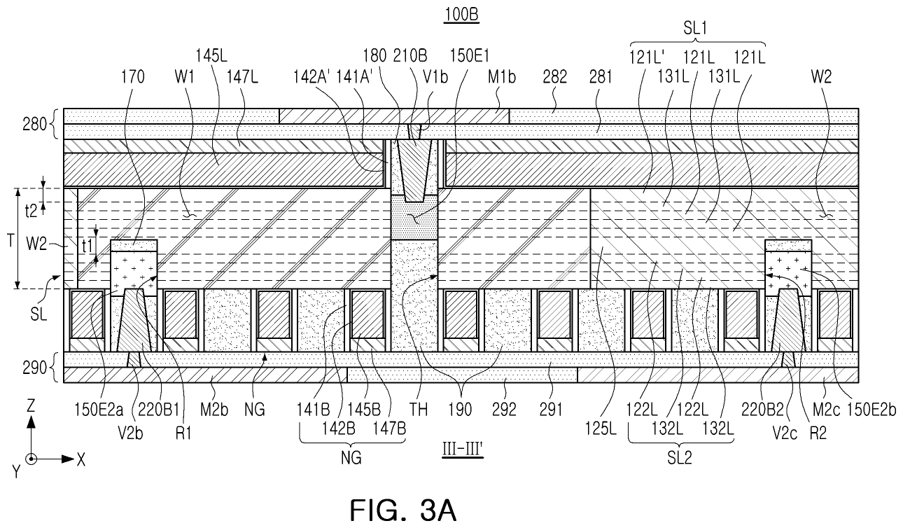

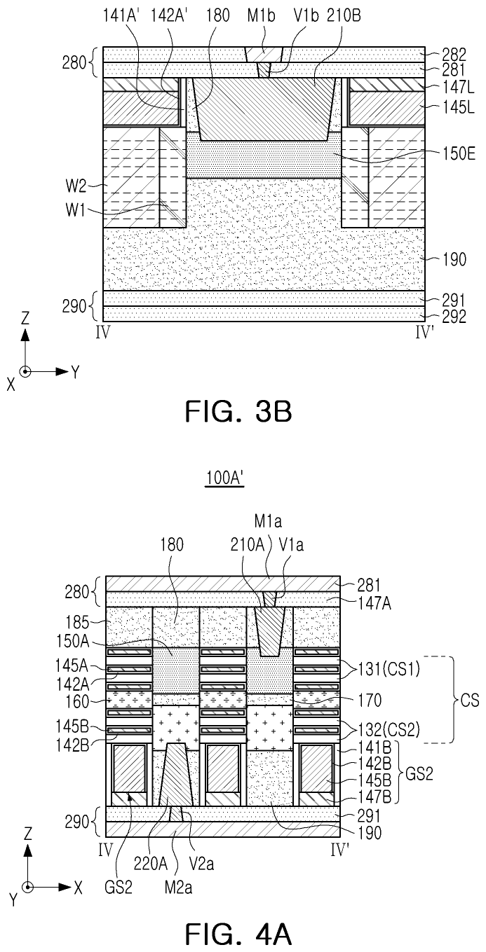

FIG. 1 is a plan diagram illustrating a semiconductor device according to an example embodiment. FIGS. 2A to 2C are cross-sectional diagrams illustrating a first device region A of a semiconductor device in FIG. 1 taken along lines I-I′, II1-II1′, and II2-II2′, respectively. FIGS. 3A and 3B are cross-sectional diagrams illustrating a second device region B of a semiconductor device in FIG. 1 taken along lines III-III′ and IV-IV′, respectively.

Referring to FIG. 1, a semiconductor device in the example embodiment may include a first device region A and a second device region B arranged in a horizontal direction (e.g., X-direction or Y-direction). Here, the first device region A may also be referred to as a “logic region” in which the logic devices 100A are implemented, and the second device region B may also be referred to as a “peripheral circuit region” in which circuit devices 100B are implemented.

Referring to FIGS. 1 and 2A to 2C, the logic device 100A of the semiconductor device 100 in the example embodiment may include a channel structure CS extending lengthwise in the first direction (e.g., the X-direction), and first and second gate structures GS1 and GS2 intersecting one region of the channel structure CS and extending lengthwise in the second direction (e.g., the Y-direction) intersecting the first direction (e.g., the X-direction).

Specifically, referring to FIG. 2A, the channel structure CS may include an insulating isolation pattern 160, first semiconductor patterns 131 stacked and spaced apart from each other in the third direction (e.g., the Z-direction) perpendicular to an upper surface of the insulating isolation pattern 160, and a second semiconductor patterns 132 stacked and spaced apart from each other in the third direction (e.g., the Z-direction) perpendicular to a lower surface of the insulating isolation pattern 160. Among the second semiconductor patterns 132, the insulating isolation pattern 160 may be disposed on the uppermost semiconductor pattern, and the first semiconductor patterns 131 may be stacked and spaced apart from each other on the insulating isolation pattern 160. The insulating isolation pattern 160 may be arranged to overlap the first channel layers 131 and the second channel layers 132 in a third direction (e.g., the Z-direction), a vertical direction.

As described above, the first and second semiconductor patterns 131 and 132 may be isolated from each other by the insulating isolation pattern 160, and each of the first and second semiconductor patterns 131 and 132 may be provided as an independent channel structure. For example, the first semiconductor patterns 131 may be included in the first channel structure CS1, and the second semiconductor patterns 132 may be included in the second channel structure CS2.

In some example embodiments, a plurality of the first semiconductor patterns 131 (e.g., two or three first semiconductor patterns) may be provided. For example, the first semiconductor patterns 131 may be formed of or include silicon (Si) or silicon germanium (SiGe). Similarly, a plurality of the second semiconductor layers 132 may be provided (e.g., two or three second semiconductor layers). For example, the second semiconductor patterns 132 may be formed of or include silicon (Si) or silicon germanium (SiGe). In some example embodiments, the first and second semiconductor patterns 131 and 132 may be silicon semiconductor patterns.

The insulating isolation pattern 160 may include an insulating material, and may be formed of or include, for example, at least one of silicon nitride, silicon oxynitride, or silicon carbonitride. The insulating isolation pattern 160 may be a single insulating material layer, but in some example embodiments, the insulating isolation pattern 160 may include a plurality of insulating material layers.

The gate structure employed in the example embodiment may include a first gate structure GS1 for the first channel structure CS1 and a second gate structure GS2 for the second channel structure CS2.

Referring to FIGS. 1, 2A and 2C, the first gate structure GS1 may intersect one region of the first channel structure CS1, may extend lengthwise in the second direction (e.g., the Y-direction), and may surround the first semiconductor patterns 131, respectively. Similarly, the second gate structure GS2 may intersect one region of the second channel structure CS2, may extend lengthwise in the second direction (e.g., the Y-direction) and may surround each of the second semiconductor patterns 132.

Specifically, referring to FIGS. 2A and 2C, the first gate structure GS1 employed in the example embodiment may include a first gate electrode 145A surrounding the first semiconductor patterns 131, and a first gate insulating layer 142A disposed between the first semiconductor patterns 131 and the first gate electrode 145A. Also, the first gate structure GS1 may include first gate spacers 141A disposed on both sidewalls of the upper portion of the first gate electrode 145A disposed on an uppermost first semiconductor pattern 132 of the first gate electrode 145A and a first gate capping layer 147A disposed on the upper portion between the first gate spacers 141A. The first gate capping layer 147A may contact an upper surface of the first gate electrode 145A, and the first gate electrode 145A may surround and contact surfaces of the first gate insulating layer 142A. In some example embodiments, the first gate insulating layer 142A may be formed between the first semiconductor patterns 131 and the first gate layer 142A, may also extend in the second direction (e.g., the Y-direction) along the upper surface of the insulating isolation pattern 160, and may be formed on the internal sidewall of the first gate spacers 141A.

Similarly, the second gate structure GS2 employed in the example embodiment may include a second gate electrode 145B surrounding the second semiconductor patterns 132, a second gate insulating layer 142B disposed between the second semiconductor patterns 132 and the second gate electrode 145B, second gate spacers 141B disposed on both sidewalls of second gate electrode 145B, and a second gate capping layer 147B disposed on the electrode portion between the first gate spacers 141A. The second gate capping layer 147B may contact a lower surface of the second gate electrode 145B, and the second gate electrode 145B may surround and contact surfaces of the second gate insulating layer 142B.

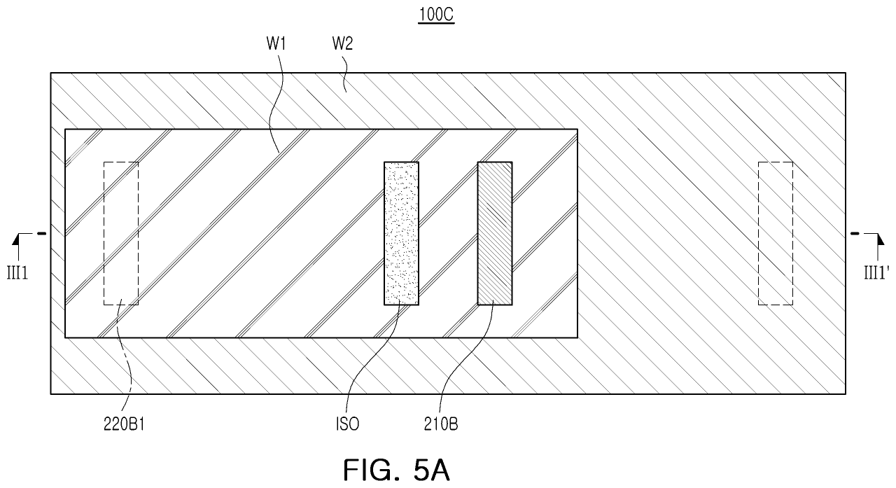

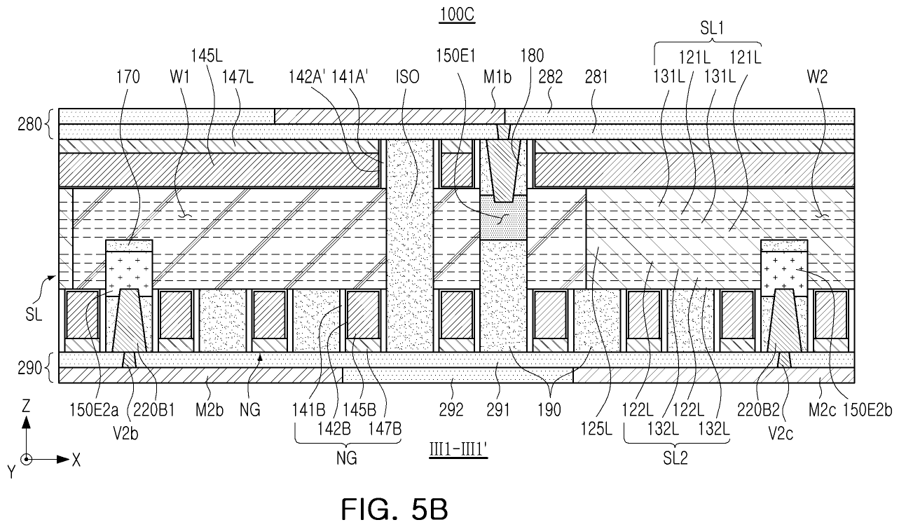

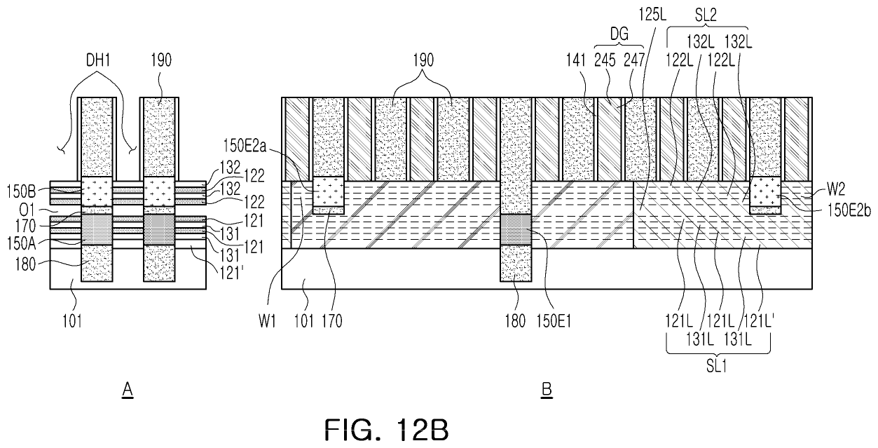

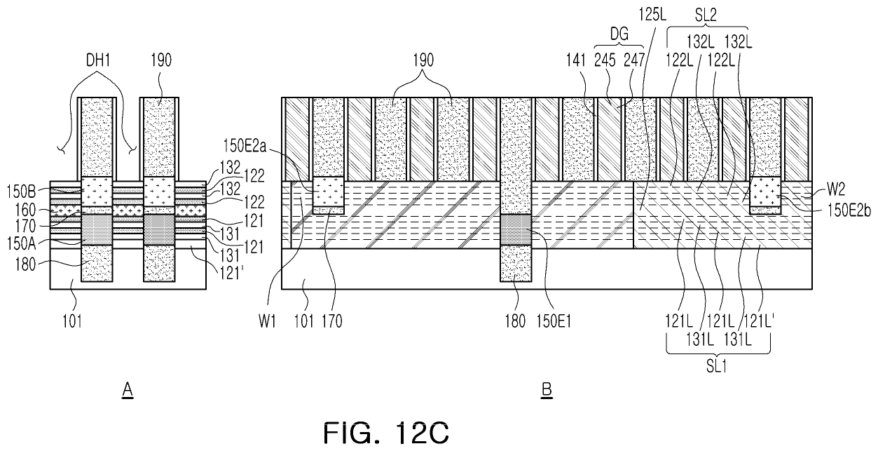

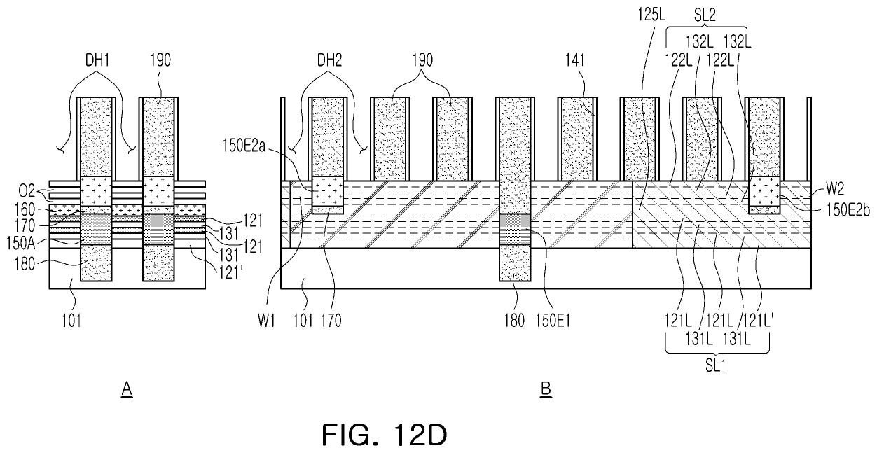

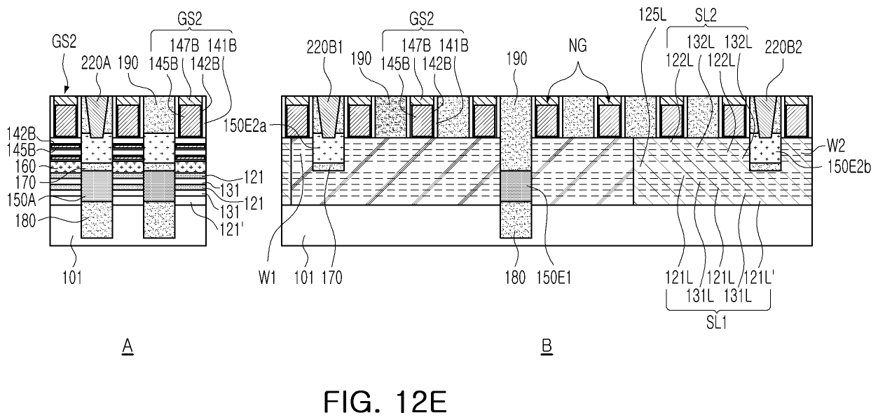

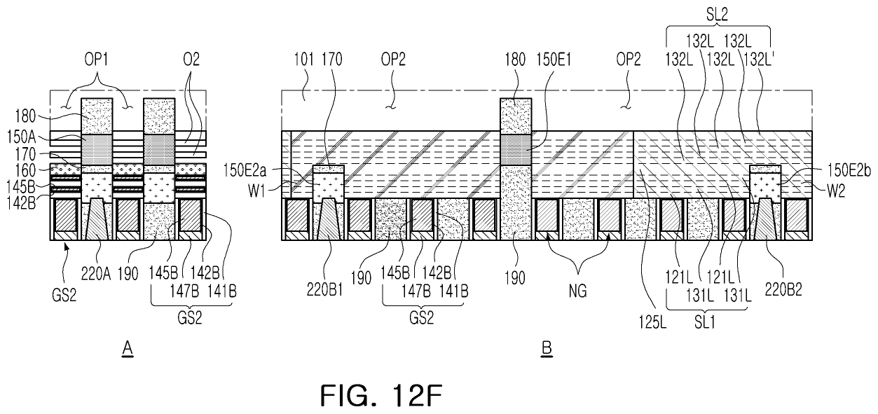

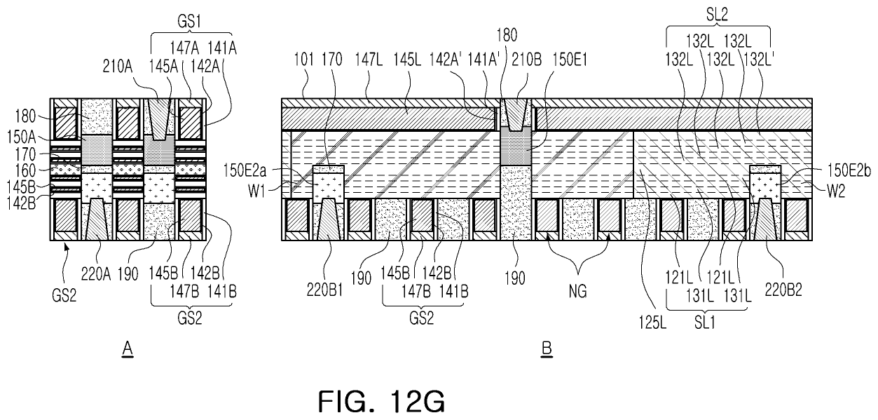

In the example embodiment, the first gate structure GS1 may be configured as a structure formed in a backside process (e.g., FIGS. 12F and 12G), similarly to a process of forming the second gate structure GS2. That is, as illustrated in FIG. 2A, the first gate structure GS1 may have a structure (e.g., a vertically symmetrical structure) similar to the second gate structure GS2. Alternatively, in another example embodiment, when the first gate structure GS1 is formed in the front process of forming the second gate structure GS2 (e.g., FIGS. 12D and 12E), portions disposed on the uppermost first semiconductor pattern 131 (e.g., the upper portion of the first gate electrode 145A, a portion of the first gate insulating layer 142A and the first gate spacer 141A) may not be provided (see FIG. 5A).

The first and second gate electrodes 145A and 145B employed in the example embodiment may include different conductive materials. For example, the first and second gate electrodes 145A and 145B may be formed of or include at least one of W, Ti, Ta, Mo, TiN, TaN, WN, TiON, TiAlC, TiAlN, and TaAlC. In some example embodiments, the first and second gate electrodes 145A and 145B may be formed of or include a semiconductor material, such as doped polysilicon. At least one of the first and second gate electrodes 145A and 145B may include a multilayer structure formed of different materials.

The first and second gate insulating layers 142A and 142B may include different dielectric materials. For example, the first and second gate insulating layers 142A and 142B may be formed of or include oxide, nitride, or high-x material. The high-x material may refer to a dielectric material having a higher dielectric constant than that of silicon oxide (SiO₂). The high-x material may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The first and second gate spacers 141A and 141B may include the same insulating material or partially different insulating materials. For example, the first and second gate spacers 141A and 141B may be formed of or include at least one of silicon oxide, silicon nitride, and silicon oxynitride. In some example embodiments, at least one of the first and second gate spacers 141A and 141B may include a multilayer structure formed of different materials. The first and second gate capping layers 147A and 147B may be formed of or include, for example, silicon nitride, silicon oxynitride, silicon carbonitride, or silicon oxycarbonitride.

The logic device 100A in the example embodiment may include a pair of first source/drain patterns 150A disposed on both sides of the first channel structure CS1 in the first direction (e.g., the X-direction), and a pair of second source/drain patterns 150B disposed on both sides of the second channel structure CS2 in the first direction (e.g., the X-direction). The pair of first source/drain patterns 150A may be connected to both sides of the first semiconductor patterns 131, and the pair of second source/drain patterns 150B may be connected to both sides of the second semiconductor patterns 132. The first and second source/drain patterns 150A and 150B may be arranged to overlap each other in the vertical third direction (e.g., the Z-direction).

The first source/drain patterns 150A may include epitaxial growth from both side surfaces of the first channel layer 131. Similarly, the second source/drain patterns 150B may include epitaxial growth from both side surfaces of second channel layers 132.

The first and second source/drain patterns 150A and 150B may include a semiconductor epitaxial layer such as silicon (Si). The first and second source/drain patterns 150A and 150B may include different types and/or concentrations of impurities. In some example embodiments, the first source/drain patterns 150A may include an epitaxial layer doped with a first conductivity-type impurity, and the second source/drain patterns 50B may include an epitaxial layer doped with a second conductivity-type impurity.

For example, the first source/drain patterns 150A may be formed of or include silicon (Si) doped with N-type impurities. The second source/drain patterns 150B may be formed of or include silicon or silicon germanium (SiGe) doped with P-type impurities. Accordingly, cross-sectional surfaces of the first and second source/drain patterns 150A and 150B in the second direction (e.g., the Y-direction) may have different shapes. For example, the cross-sectional surface of the first source/drain pattern 150A may have a polygonal shape having gentle angles. The cross-sectional surface of the second source/drain patterns 150B may have a pentagonal shape (see FIG. 2B).

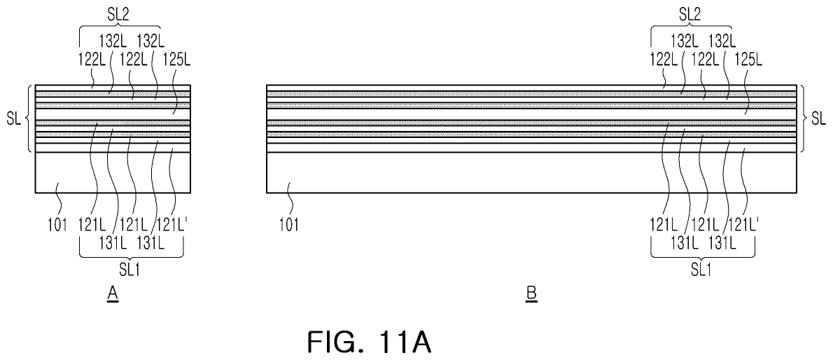

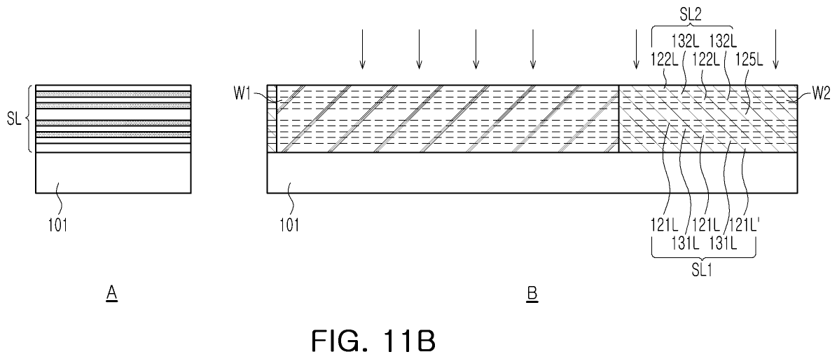

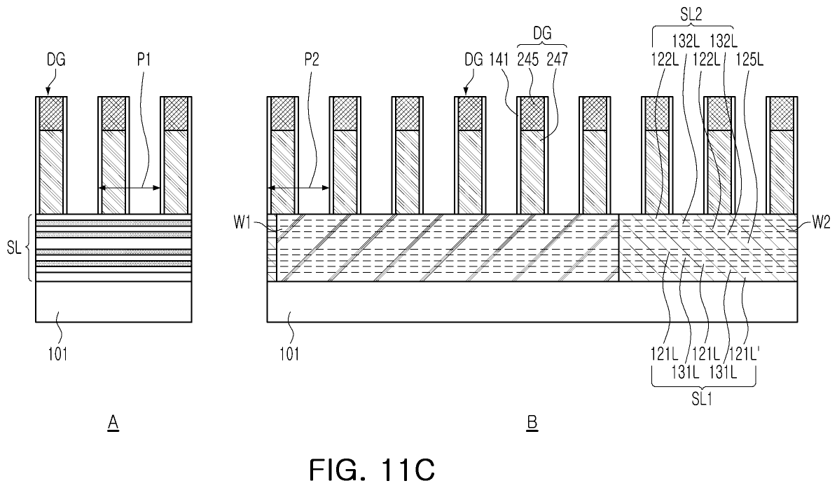

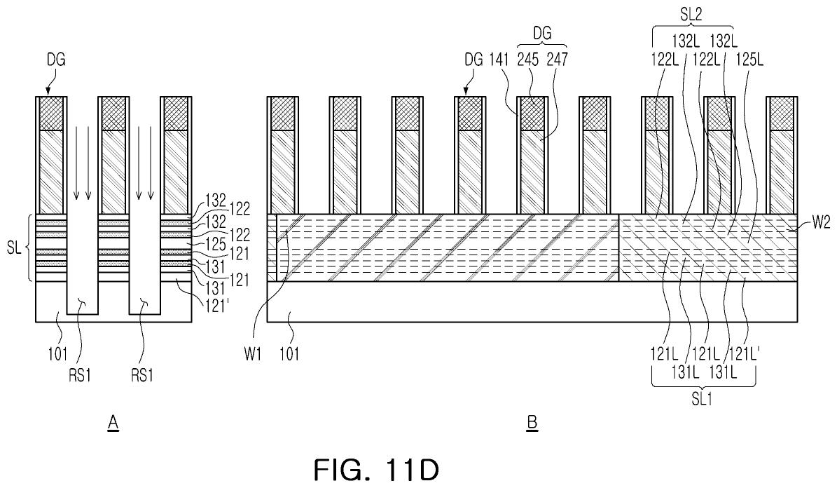

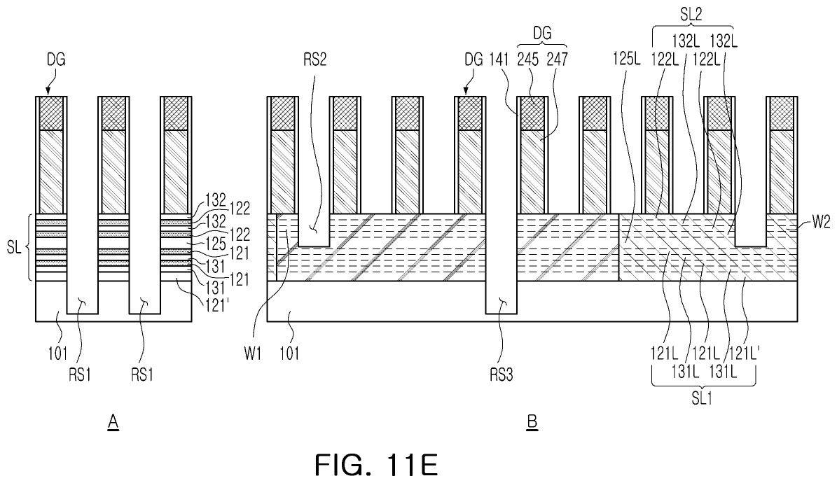

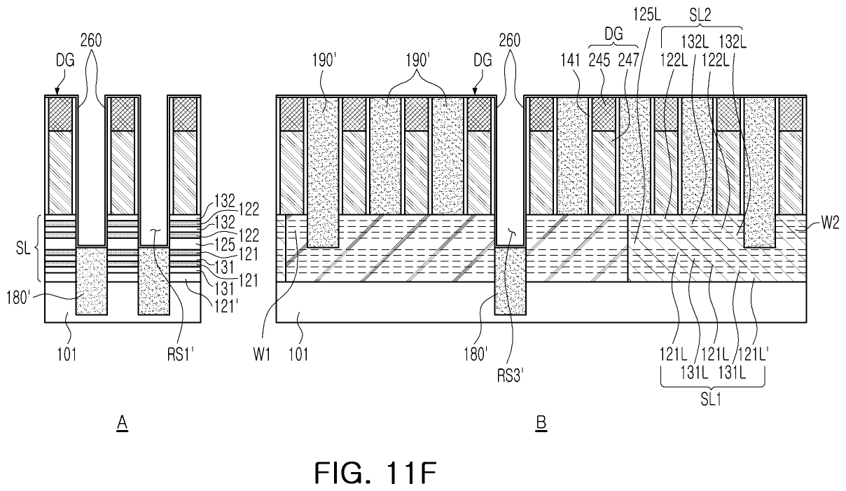

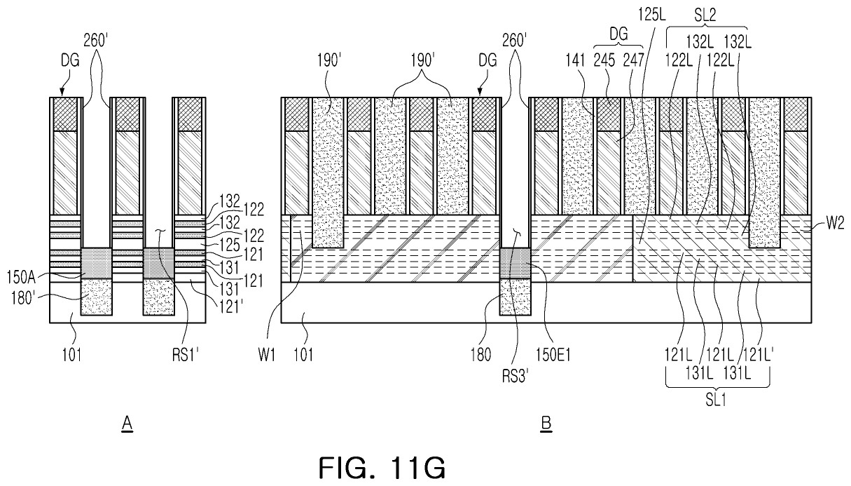

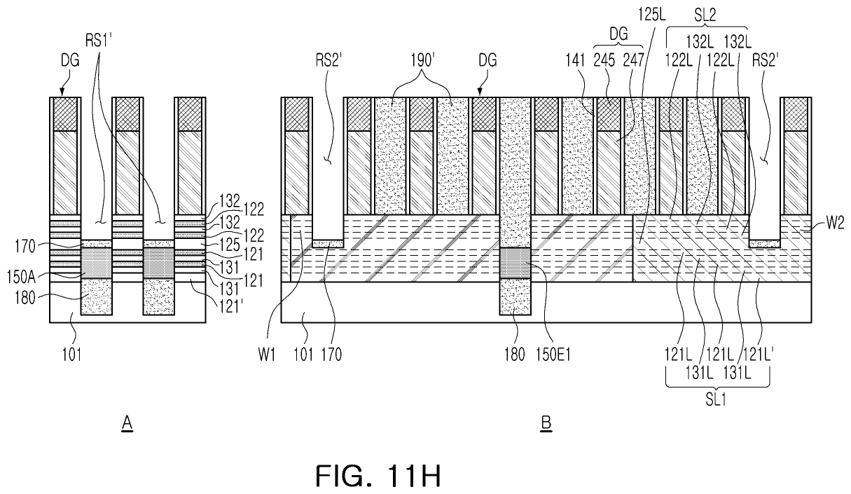

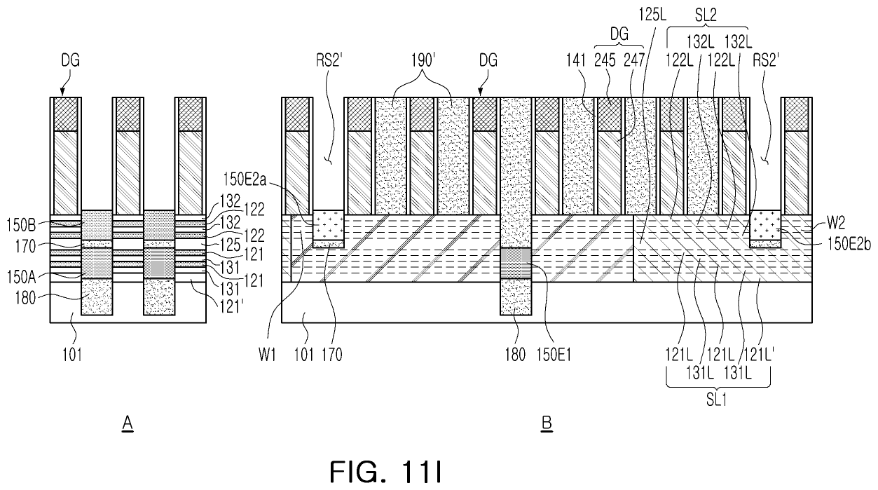

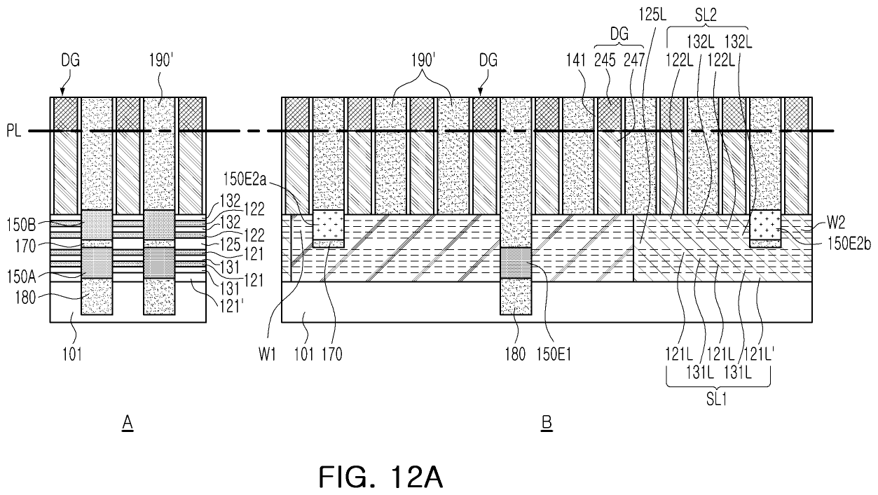

The logic device 100A in the example embodiment may include a multilayer insulating structure in a space in which first and second source/drain patterns 150A and 150B are disposed. As illustrated in FIG. 2B, the multilayer insulating structure may further include a first gap-fill insulating layer 180 and a second gap-fill insulating layer 190, and an isolation insulating layer 170 disposed therebetween. In the manufacturing process (FIG. 11A to FIG. 11I and FIG. 12A to FIG. 12G), in the state in which the cross-sectional surface in FIG. 2B is inverted, the first gap-fill insulating layer 180, the isolation insulating layer 170 and the second gap-fill insulating layer 190 may be formed in order. The first gap-fill insulating layer 180 may have a surface substantially coplanar with a level of an upper surface of the first source/drain patterns 150A. The isolation insulating layer 170 may be formed to cover the first source/drain patterns on the first gap-fill insulating layer 180. The second gap-fill insulating layer 190 may be formed to cover the second source/drain patterns 150B on the isolation insulating layer 170. In example embodiments, the isolation insulating layer 170 may contact the first gap-fill insulating layer 180 and the second gap-fill insulating layer 190.

The first and second gap-fill insulating layers 180 and 190 may be silicon oxide. For example, the first and second gap-fill insulating layers 180 and 190 may be spin-on hardmask (SOH), flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD), or a combination thereof. The first and second gap-fill insulating layers 180 and 190 may be formed using a chemical vapor deposition (CVD), a flowable CVD (FCVD) process, or a spin coating process.

The isolation insulating layer 170 is provided to isolate the first and second source/drain patterns 150A and 150B, and may include an insulating material which may be the same as or similar to the first and second gap-fill insulating layers 180 and 190. For example, the isolation insulating layer 170 may include silicon oxide, silicon oxynitride, silicon carbonitride, or silicon nitride.

In some example embodiments, the isolation insulating layer 170 may be formed relatively conformally using a process such as atomic layer deposition (ALD). In this case, the isolation insulating layer 170 may be formed relatively conformally on the upper surface of the first gap-fill insulating layer 180 along the surface of the first source/drain patterns 150A.

The logic device 100A in the example embodiment may further include a first upper contact 210A connected to the first source/drain pattern 150A and a first lower contact 220A connected to the second source/drain pattern 150B. The logic device 100A may further include contacts (not illustrated) connected to the first or second gate electrodes 145A and 145B.

The first upper contact 210A may penetrate through the first gap-fill insulating layer 180 and may be connected to the first source/drain pattern 150A, and the first lower contact 220A may penetrate through the second gap-fill insulating layer 190 and may be connected to the second source/drain pattern 150B. For example, the first upper contact 210A may contact the first source/drain pattern 150A, and the first lower contact 220A may contact the second source/drain pattern 150B. In example embodiments, the first upper and lower contacts 210A and 220A may include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (Al), cobalt (Co), ruthenium (Ru), and molybdenum (Mo).

As such, logic devices 100A in the example embodiment may include stacked upper and lower transistors. The upper transistor may include a first channel structure CS1, a first gate structure GS1, and a first source/drain patterns 150A, and the lower transistor may include a second channel structure CS2, a second gate structure GS2, and a second source/drain patterns 150B. Each of the upper and lower transistors may be a multi bridge channel FET (MBCFET™). The upper transistor may be configured as one of N-type MOSFET and P-type MOSFET, and the lower transistor may be the other of P-type MOSFET and N-type MOSFET. In the example embodiment, each of the upper transistors may be an N-type MOSFET, and the lower transistors may be a P-type MOSFET.

As described above, the semiconductor device 100 in the example embodiment may include a first device region A and a second device region B disposed in a different region in the horizontal direction. The second device region B may include a circuit device 100B, included in a peripheral circuit. Since the circuit device 100B in the example embodiment is formed through a series of processes combined with the process of forming of the logic device 100A described above, the components may be interrelated. This manufacturing process will be described in greater detail later with reference to FIGS. 11A to 11I and FIGS. 12A to 12G.

Referring to FIGS. 1, 3A and 3B, the circuit device 100B of the semiconductor device 100 in the example embodiment may include a semiconductor stack body SL in which semiconductor layers having different compositions are stacked, and a plurality of inactive gate structures NG disposed and spaced apart from each other on the lower surface of the semiconductor stack body SL.

The semiconductor stack body SL may be provided as a semiconductor bulk structure to form the circuit device 100B. The semiconductor stack body SL may include at least one of a first conductivity-type impurity region W1 and a second conductivity-type impurity region W2. In the example embodiment, the semiconductor stack body SL may include the first conductivity-type impurity region W1 and the second conductivity-type impurity region W2 surrounding the first conductivity-type impurity region W1. For example, the second conductivity-type impurity region W2 may surround side surfaces of the first conductivity-type impurity region W1 in a plan view.

In the example embodiment, each of the plurality of inactive gate structures NG may correspond to the second gate structure GS2, but may be understood as a dummy structure not involved in driving. The plurality of inactive gate structure NG employed in the example embodiment may have a structure similar to a portion of the second gate structure GS2 (a portion disposed below the second channel structure CS2), and may be formed of the same material. Specifically, each of the plurality of inactive gate structure NG may include a second gate electrode 145B extending in the second direction (e.g., the Y-direction) on the lower surface of the semiconductor stack body SL, a second gate insulating layer 142B disposed between the lower surface of semiconductor stack body SL and the second gate electrode 145B, second gate spacers 141B disposed on both sidewalls of the second gate electrode 145B, and a second gate capping layer 147B disposed on the second gate electrode 145B between the second gate spacers 141B.

The semiconductor stack body SL employed in the example embodiment may have a structure corresponding to the semiconductor stack body (SL in FIG. 11A) forming the channel structure CS of the logic device 100A.

As illustrated in FIGS. 3A and 3B, the semiconductor layers may include an intermediate semiconductor layer 125L, upper stack body SL1 including first upper semiconductor layers 121L and second upper semiconductor layers 131L alternately stacked on the upper surface of the intermediate semiconductor layer 125L, and a lower stack body SL2 having first lower semiconductor layers 122L and second lower semiconductor layers 132L alternately stacked on the lower surface of the intermediate semiconductor layer 125L. The first upper semiconductor layers 121L may include an uppermost first upper semiconductor layers 121L′.

Each of the second upper semiconductor layers 131L may correspond to the first semiconductor patterns 131 included in the channel of the logic device 100A. That is, each of the second upper semiconductor layers 131L may include substantially the same material layer as that of the first semiconductor patterns 131 and may have substantially the same thickness. Similarly, the second lower semiconductor layers 132L may correspond to the second semiconductor patterns 132 included in the channel of logic device 100A, respectively. For example, each of the second lower semiconductor layers 132L may include substantially the same material layer as that of the second semiconductor patterns 132 and may have substantially the same thickness. However, in the semiconductor stack body, a portion of components (e.g., Ge) may diffuse during the process, such that boundaries of the semiconductor layers and the distribution of a portion of components may change.

Also, the first upper semiconductor layers 121L and the first lower semiconductor layers 122L may correspond to the first and second sacrificial patterns (e.g., first and second sacrificial patterns 121 and 122 in FIGS. 11A and 11B) to form the first and second channel structures CS1 and CS2, respectively. The intermediate semiconductor layer 125L may correspond to intermediate sacrificial layer (e.g., intermediate sacrificial layer 125 in FIGS. 11A and 11B) to form the insulating isolation pattern 160 between the first and second channel structures CS1 and CS2, respectively.

In some example embodiments, the thickness t1 of the intermediate semiconductor layer 125 may be greater than the thickness of each of the first and second upper semiconductor layers 121L and 131L or the first and second lower semiconductor layers 122L and 132L.

In some example embodiments, the lower stack body SL2 may be disposed such that the first lower semiconductor layer 122L and the second lower semiconductor layer 132L may be disposed as at least the uppermost layer (i.e., the layer in contact with the intermediate semiconductor layer 125) and the lowermost layer of the lower stack body SL2, respectively.

Alternatively, the upper stack body SL1 may be arranged such that the first upper semiconductor layers 121L′ and 121L may be disposed as at least the uppermost layer and lowermost layer of the upper stack body SL1. Here, the thickness t2 of the first upper semiconductor layer 121L′, which is the uppermost layer, may be larger than each of the thicknesses of the other first upper semiconductor layers 121L.

In the example embodiment, a lower surface of the semiconductor stack body SL may have a level substantially corresponding to a level of the lower surface of the channel structure (e.g., channel structure CS in FIG. 3A). Also, the upper surface of the semiconductor stack body SL may have a level higher than a level of the upper surface of the channel structure (e.g., channel structure CS in FIG. 3A) by the thickness t2 of the first upper semiconductor layer 121L′, which is the uppermost layer. In other words, the thickness T of the semiconductor stack body SL may be greater than the height H of the channel structure (e.g., channel structure CS in FIG. 3A) by the thickness t2 of the first upper semiconductor layer 121L′, which is the uppermost layer.

In the example embodiment, semiconductor layers of different compositions may have different germanium composition ratios (e.g., 0 to 60%). For example, the second upper semiconductor layers 131L and the second lower semiconductor layers 132L may include silicon, and the first upper semiconductor layers 121L, the first lower semiconductor layers 122L, and the intermediate semiconductor layer 125L may include silicon germanium. The intermediate semiconductor layer 125L may have a concentration of germanium greater than a concentration of germanium of each of the first upper semiconductor layers 121L and the first lower semiconductor layers 122L.

In the example embodiment, the first lower semiconductor layers 122L may have a concentration of germanium greater than the concentration of germanium of each of the first upper semiconductor layers 121L. However, an example embodiment thereof is not limited thereto, and the first upper semiconductor layers 121L and the first lower semiconductor layers 122L may have the same concentration of germanium (e.g., see FIGS. 5A and 5B).

The semiconductor stack body SL1 may have at least one recess R1 and R2 formed on the lower surface and at least one through-hole TH penetrating through the semiconductor stack body SL. At least one recess R1 and R2 may be disposed between at least one pair of adjacent inactive gate structures among the plurality of inactive gate structures NG, and may be formed to a depth penetrating through the lower stack body SL2. At least one through-hole TH may be disposed between at least one pair of other adjacent inactive gate structures among the plurality of inactive gate structures NG. In the example embodiment, the semiconductor stack body SL may include two recesses R1 and R2 and a single through-hole TH.

Referring to FIGS. 3A and 3B, the circuit device 100B in the example embodiment may be configured as a PNP device having a semiconductor stack body SL, a first conductivity-type epitaxial pattern 150E1, and two second conductivity-type epitaxial patterns 150E2a and 150E2b.

As described above, the semiconductor stack body SL may include a first conductivity-type impurity region W1 and a second conductivity-type impurity region W2 surrounding the first conductivity-type impurity region W1. The first conductivity-type impurity region W1 may be configured as an N-type impurity region, and the second conductivity-type impurity region W2 may be configured as a P-type impurity region.

The first conductivity-type epitaxial pattern 150E1 and the second conductivity-type epitaxial patterns 150E2a and 150E2b may be epitaxial layers grown in the same process as the process of forming the first source/drain patterns 150A and the second source/drain patterns 150B of the logic device 100A, respectively.

Specifically, the first conductivity-type epitaxial pattern 150E1 may be formed together with the first source/drain patterns 150A of the logic device 100A and may include an epitaxial layer of the same material. Also, the first conductivity-type epitaxial pattern 150E1 and the first source/drain patterns 150A may be disposed on substantially the same level. Similarly, each of the second conductivity-type epitaxial patterns 150E2a and 150E2b may be formed together with the second source/drain patterns 150B of the logic device 100A and may include an epitaxial layer of the same material. Also, the second conductivity-type epitaxial patterns 150E2a and 150E2b and the second source/drain patterns 150B may be disposed on substantially the same level.

The first and second recess R1 and R2 and through-hole TH may define a region in which one first conductivity-type epitaxial pattern 150E1 and two second conductivity-type epitaxial patterns 150E2a and 150E2b are formed. In the example embodiment, the first and second recesses R1 and R2 may be disposed in the first and second conductivity-type impurity regions W1 and W2, respectively, and the through-hole TH may be disposed in the first conductivity-type impurity region W1 between the first and second recesses R1 and R2.

The first conductivity-type epitaxial pattern 150E1 may be disposed in the through-hole TH, and the second conductivity-type epitaxial patterns 150E2a and 150Eb may be disposed in the first and second recess R1 and R2, respectively. The first conductivity-type epitaxial pattern 150E1 may be disposed on a level higher than a level of the second conductivity-type epitaxial patterns 150E2a and 150E2b in the through-hole TH.

In the example embodiment, the first conductivity-type epitaxial pattern 150E1 may be an N-type semiconductor pattern, similar to the first source/drain patterns 150A, and the second conductivity-type epitaxial patterns 150E2a and 150E2b may be P-type semiconductor patterns, similar to the second source/drain patterns 150B.

Through this arrangement, as illustrated in FIG. 3A, the circuit device 100B in the example embodiment may be implemented as a PNP bipolar transistor including a second conductivity-type epitaxial pattern 150E2a as an emitter, a first conductivity-type epitaxial pattern 150E1 as a base, and a second conductivity-type epitaxial pattern 150E2b as a collector.

As described above, the recesses R1 and R2 and the through-hole TH may define a region in which the first conductivity-type epitaxial pattern 150E1 and the second conductivity-type epitaxial patterns 150E2a and 150E2b are formed. In addition to designing the impurity region of the semiconductor stack body SL, various circuit devices may be implemented by configuring the positions of the first and second recesses R1 and R2 and the through-hole TH.

Referring to FIGS. 3A and 3B, the circuit device 100B in the example embodiment may include an isolation insulating layer 170, a first gap-fill insulating layer 180, and a second gap-fill insulating layer 190.

The isolation insulating layer 170 may be disposed between the bottom surface of the first and second recesses R1 and R2 and the second conductivity-type epitaxial patterns 150E2a and 150E2b. The isolation insulating layer 170 may contact the second conductivity-type epitaxial patterns 150E2a and 150E2b. The isolation insulating layer 170 may be formed by the same process as the process of forming the isolation insulating layer 170 of the logic device 100A (see FIG. 11H). The first gap-fill insulating layer 180 may be disposed on the first conductivity-type epitaxial pattern 150E1 in the through-hole TH. The first gap-fill insulating layer 180 may contact the first conductivity-type epitaxial pattern 150E1. The second gap-fill insulating layer 190 may be disposed between the lower surface of the semiconductor stack body SL and the plurality of inactive gate structure NG. In the example embodiment, the second gap-fill insulating layer 190 may partially fill the through-hole TH from the lower surface of the semiconductor stack body SL to the first conductivity-type epitaxial pattern 150E1. The second gap-fill insulating layer 190 may contact the first conductivity-type epitaxial pattern 150E1.

The circuit device 100B in the example embodiment may include a capping structure including an electrode material layer 145L and a capping insulating layer 147L disposed in order on the upper surface of the semiconductor stack body SL.

The electrode material layer 145L and the capping insulating layer 147L may be provided as a layer structure, but may be formed together in the process of forming of the first gate electrode 145A and the first gate capping layer 147A of the logic device 100A. The electrode material layer 145L may include the same material as the material of the first gate electrode 145A. Also, the capping insulating layer 147L may include the same material as the material of the first gate capping layer 147A.

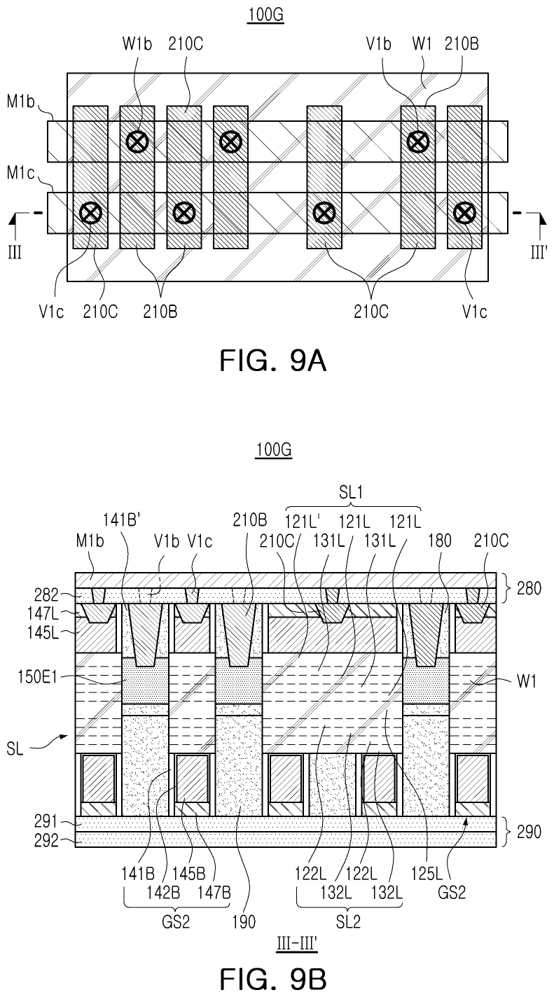

In the example embodiment, a second gate spacer 141A′ and a second gate insulating layer 142A′ may be disposed between the capping structure and the first gap-fill insulating layer 180. The second gate spacer 141A′ and the second gate insulating layer 142A′ of the circuit device 100B may be formed together in the process of forming of the second gate spacer 141A and the second gate insulating layer 142A of the logic device 100A. The second gate spacer 141A′ may include the same material as that of the second gate spacer 141A. Also, the second gate insulating layer 142A may include the same material as the material of second gate insulating layer 142A′. In some example embodiments, a portion of the components related to the first gate structure GS1 may not be included in the circuit device. For example, in the process of forming of the second gate insulating layer 142A, the second gate insulating layer 142A′ may not be provided by masking the second device region B (see FIG. 9B).

The circuit device 100B in the example embodiment may further include a second upper contact 210B connected to the first conductivity-type epitaxial pattern 150E1, and second lower contacts 220B1 and 220B2 connected to the second conductivity-type epitaxial patterns 150E2a and 150E2b, respectively.

The second upper contact 210B may penetrate through the first gap-fill insulating layer 180 and may be connected to the first conductivity-type epitaxial pattern 150E1, and the second lower contacts 220B1 and 220B2 may penetrate through the second gap-fill insulating layer 190 and may be connected to the second conductivity-type epitaxial pattern 150E2a and 150E2b, respectively. For example, the second upper contact 210B may contact the first conductivity-type epitaxial pattern 150E1, and second lower contacts 220B1 and 220B2 may contact the second conductivity-type epitaxial patterns 150E2a and 150E2b, respectively. For example, the second upper and lower contacts 210B, 220B1, and 220B2 may be formed of or include at least one of titanium nitride (TiN), tantalum nitride (TaN), tungsten nitride (WN), tungsten carbon nitride (WCN), titanium (Ti), tantalum (Ta), tungsten (W), copper (Cu), aluminum (Al), Cobalt (Co), ruthenium (Ru), and molybdenum (Mo).

The semiconductor device 100 in the example embodiment may have a double-sided interconnection structure including a first interconnection structure 280 and a second interconnection structure 290. The double-sided interconnection structure may be applied to both the first and second device regions A and B, and may be configured to electrically connect the logic devices 100A to the circuit devices 100B. The first interconnection structure 280 may be provided on the upper surface of the semiconductor device 100, and the second interconnection structure 290 may be provided on the lower surface of the semiconductor device 100.

Referring to FIGS. 2A to 2C and FIGS. 3A and 3B, the first interconnection structure 280 may include first interconnection insulating layers 281 and 282 and first and second upper interconnection lines M1a and M1b disposed in the first interconnection insulating layer 281 and 282. For example, in the logic device 100A, the first upper interconnection line M1a may be connected to the first upper contact 210A through the metal vias Vla. In the circuit device 100B, the second upper interconnection line M1a may be connected to the second upper contact 210B through the metal vias V1b.

Similarly, the second interconnection structure 290 may include second interconnection insulating layers 291 and 292 and the first to third lower interconnection lines M2a, M2b, and M2c disposed in the first interconnection insulating layer 291 and 292. For example, in the logic device 100A, the first lower interconnection line M2a may be connected to the first lower contact 220A through the metal vias V2a. In the circuit device 100B, the second lower interconnection lines M1b and the M1c may be connected to the second lower contacts 220B1 and 220B2 through the metal vias V2b and V2c, respectively.

For example, the first and second interconnection insulating layers 281 and 282 and 291 and 292 may be formed of or include silicon oxide, silicon oxynitride, SiOC, SiCOH, or a combination thereof. For example, the upper and lower interconnection lines M1a, M1b and M2a, M2b, M2c and the metal vias V1a, V1b and V2a, V2b, V2c may be formed of or include copper or a copper-containing alloy. In some example embodiments, the interconnection lines and respective metal vias may be formed together using a dual-damascene process.

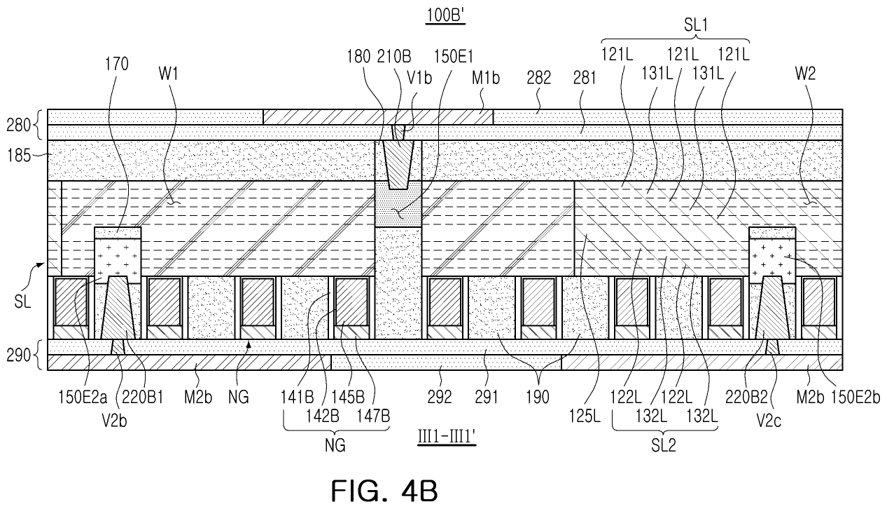

FIG. 4A is a cross-sectional diagram illustrating a first device region of a semiconductor device taken along line I-I′ according to an example embodiment. FIG. 4B is a cross-sectional diagram illustrating a second device region of a semiconductor device taken along line III-III′ according to an example embodiment.

Referring to FIGS. 4A and 4B, the semiconductor device in the example embodiment may be similar to the semiconductor device 100 illustrated in FIGS. 1 to 3B other than the configuration in which the first gate structure of the logic device and the process of a first gate structure GS1 are changed, and the configuration in which the semiconductor stack body SL of the circuit device and an upper surface structure thereof are changed. Also, unless otherwise indicated, the components in the example embodiment may be understood with reference to the descriptions of the same components of the semiconductor device 100 illustrated in FIGS. 1 to 3B.

Differently from the aforementioned example embodiment, the semiconductor device, particularly the logic device 100A′, in the example embodiment, may be formed using a front process, similarly to the process in which the second gate structure GS2 is formed (e.g., the processes in FIGS. 12D and 12E). For example, before the process of forming the second gate structure GS2 (see the process in FIG. 12D), the process of forming the first gate structure GS1 may be performed. The first sacrificial pattern (e.g., first sacrificial pattern 121 in FIG. 12C) to form the first gate structure GS1 may be preferentially removed, and the first gate insulating layer 142A and the first gate electrode 145A may be formed.

Accordingly, in the logic device 100A in the example embodiment, the upper structure portion such as the first gate electrode portion and the first gate capping layer disposed on the first channel structure CS1 may not be provided other than the gate structure portion surrounding the uppermost first semiconductor pattern 131, as illustrated in FIG. 4A.

As illustrated in FIG. 4B, the circuit device in the example embodiment may not include an electrode material layer (e.g., electrode material layer 145L in FIG. 3A) and an insulating capping layer (e.g., insulating capping layer 147L in FIG. 3A) on the semiconductor stack body SL, differently from the aforementioned example embodiment. Instead, the circuit device 100B may include an insulating portion 185 on the upper surface of the first channel structure CS. The insulating portion 185 may be formed after removing the substrate 101 (see FIG. 12F). Also, in the semiconductor stack body SL employed in circuit device 100B, differently from the aforementioned example embodiment, the thickness of the first upper semiconductor layer 121L, which is the uppermost layer of the upper stack body, may be substantially the same as the thickness of other semiconductor layers.

FIGS. 5A and 5B are a plan diagram and a lateral cross-sectional diagram illustrating a semiconductor device (e.g., a circuit device) according to an example embodiment.

Referring to FIGS. 5A and 5B, the circuit device 100C in the example embodiment may be similar to the circuit device 100B illustrated in FIGS. 3A and 3B other than the configuration in which the isolation ISO is further included between the second conductivity-type epitaxial pattern 150E2aA and the first conductivity-type epitaxial pattern 150E1 disposed in the first conductivity-type impurity region W1. Also, unless otherwise indicated, the components in the example embodiment may be understood with reference to the description of the same components of the circuit device 100B illustrated in FIGS. 3A and 3B.

The circuit device 100C in the example embodiment may further include an isolation ISO between the second conductivity-type epitaxial pattern 150E2a, which is an emitter, and the first conductivity-type epitaxial pattern 150E1, which is a base. The second conductivity-type epitaxial pattern 150E2a and the first conductivity-type epitaxial pattern 150E1 may be disposed in the same first conductivity-type impurity region W1.

In the circuit device 100B in the example embodiment, the isolation ISO may be provided as a dielectric barrier for dispersing a current flowing from the emitter to the base. The isolation ISO employed in the example embodiment may be configured as a through-hole structure and may be provided by forming a through-hole TH in which the first conductivity-type epitaxial pattern 150E1 is disposed and filling the hole with a dielectric material. This isolation ISO may be used as a dielectric barrier to prevent concentration of current in various circuit devices.

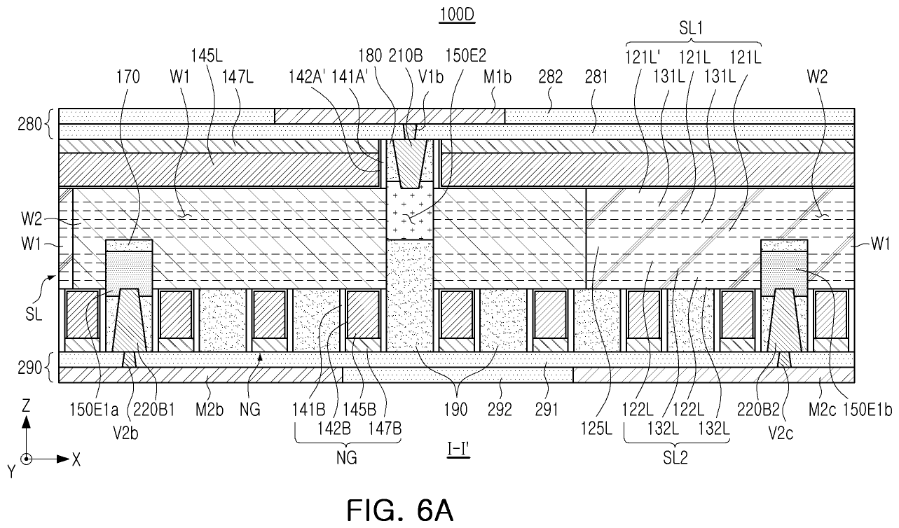

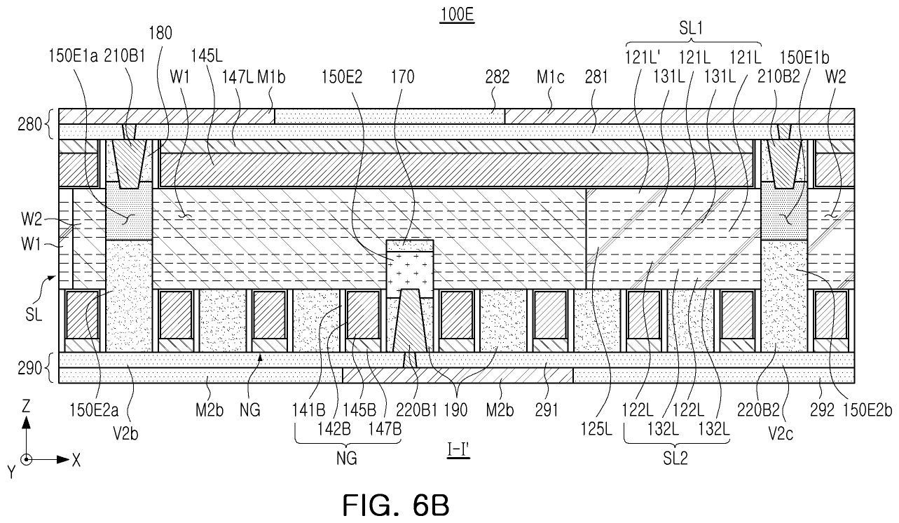

FIGS. 6A and 6B are cross-sectional diagrams illustrating a semiconductor device (e.g., a circuit device) according to an example embodiment. The circuit devices 100B, 100B′, and 100C according to the aforementioned example embodiment are illustrated as PNP bipolar devices, and the circuit devices 100D and 100E in the example embodiment may be implemented as NPN bipolar devices.

Referring to FIG. 6A, the circuit device 100D in the example embodiment may be similar to the circuit device 100B illustrated in FIGS. 3A and 3B other than the configuration in which the impurity region of the semiconductor stack body SL is changed, and the configuration in which the upper and lower positions of first conductivity-type epitaxial patterns 150E1a and 150E1b and the second conductivity-type epitaxial patterns 150E2 are changed. Also, unless otherwise indicated, the components in the example embodiment may be understood with reference to the description of the same components of the circuit device 100B illustrated in FIGS. 3A and 3B.

Differently from the aforementioned example embodiments, the circuit device 100D in the example embodiment may have a first conductivity-type impurity region W1 surrounding the second conductivity-type impurity region W2. For example, the first conductivity-type impurity region W1 may be configured as an N-type region, and the second conductivity-type impurity region W2 may be configured as a P-type region.

The circuit device 100D in the example embodiment may include two first conductivity-type epitaxial patterns 150E1a and 150E1b and second conductivity-type epitaxial patterns 150E2.

The semiconductor stack body SL may include two recesses in the lower surface and a single through-hole penetrating through the semiconductor stack body SL. Differently from the aforementioned example embodiment, in the example embodiment, two first conductivity-type epitaxial patterns 150E1a and 150E1b may be formed in two recesses, respectively, and the second conductivity-type epitaxial patterns 150E2 may be formed to be disposed on a level higher than a level of the two first conductivity-type epitaxial patterns 150E1a and 150E1b within the through-hole.

The first conductivity-type epitaxial pattern 150E1a and the second conductivity-type epitaxial patterns 150E2 may be disposed in the second conductivity-type impurity region W2, and the other first conductivity-type epitaxial patterns 150E1b may be disposed in the first conductivity-type impurity region W1. In the example embodiment, the two first conductivity-type epitaxial patterns 150E1a and 150E1b may be configured as N-type semiconductor patterns, and the second conductivity-type epitaxial patterns 150E2 may be configured as P-type semiconductor pattern. Similarly, the conductivity-type of the first and second source/drain patterns 150A and 150B of the logic device (see FIG. 2a) may also be changed.

Through this arrangement, as illustrated in FIG. 6A, the circuit device 100D in the example embodiment may be implemented as an NPN bipolar transistor including the first conductivity-type epitaxial pattern 150E1a as an emitter, the second conductivity-type epitaxial pattern 150E2 as a base, and the first conductivity-type epitaxial pattern 150E1b as collector.

Referring to FIG. 6B, the circuit device 100E in the example embodiment may be similar to the circuit device 100B illustrated in FIGS. 3A and 3B other than the configuration in which the impurity regions W1 and W2 of the semiconductor stack body SL are changed, and the positions of the first conductivity-type epitaxial patterns 150E1a and 150E1b and the second conductivity-type epitaxial patterns 150E2 are changed. Also, unless otherwise indicated, the components in the example embodiment may be understood with reference to the description of the same components of the circuit device 100B illustrated in FIGS. 3A and 3B.

The circuit device 100E in the example embodiment may have a first conductivity-type impurity region W1 surrounding the second conductivity-type impurity region W2, similarly to the circuit device 100D illustrated in FIG. 6A. For example, the first conductivity-type impurity region W1 may be configured as an N-type region, and the second conductivity-type impurity region W2 may be configured as a P-type region.

The circuit device 100E in the example embodiment may include two second conductivity-type epitaxial patterns 150E2a and 150E2b and second conductivity-type epitaxial patterns 150E2.

The semiconductor stack body SL may include a recess in the lower surface and two through-holes penetrating through the semiconductor stack body SL. Differently from the aforementioned example embodiment, in the example embodiment, two first conductivity-type epitaxial patterns 150E1a and 150E1b may formed in each of the two through-holes, and the two first conductivity-type epitaxial patterns 150E1a and 150E1b may be disposed on a level higher than a level of the second conductivity-type epitaxial patterns 150E2 within the through-hole.

The first conductivity-type epitaxial pattern 150E1a and the second conductivity-type epitaxial pattern 150E2 may be disposed in the second conductivity-type impurity region W2, and the other first conductivity-type epitaxial patterns 150E1b may be disposed in the first conductivity-type impurity region W1. In the example embodiment, the two first conductivity-type epitaxial patterns 150E1a and 150E1b may be configured as N-type semiconductor patterns, and the second conductivity-type epitaxial patterns 150E2 may configured as P-type semiconductor patterns.

Through this arrangement, as illustrated in FIG. 6B, the circuit device 100E in the example embodiment may be implemented as an NPN bipolar transistor including the first conductivity-type epitaxial pattern 150E1a as an emitter, the second conductivity-type epitaxial pattern 150E2 as a base, and the first conductivity-type epitaxial pattern 150E1b as a collector.

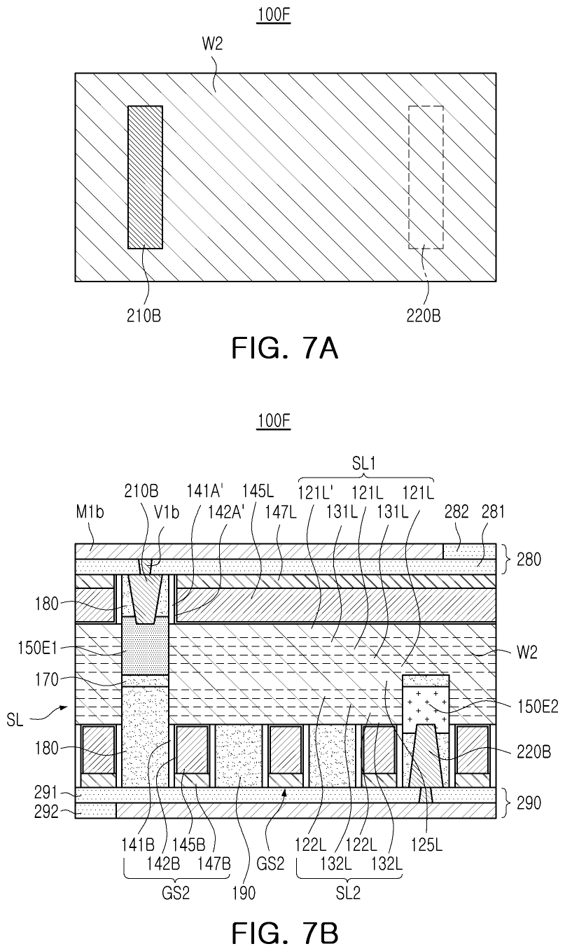

FIGS. 7A and 7B are a plan diagram and a lateral cross-sectional diagram illustrating a semiconductor device (e.g., a circuit device) according to an example embodiment.

Referring to FIGS. 7A and 7B, the circuit device 100F in the example embodiment may be similar to the circuit device 100B illustrated in FIGS. 3A and 3B other than the configuration in which the semiconductor stack body SL has a single impurity region W1 and a single first conductivity-type epitaxial pattern 150E1 and a single second conductivity-type epitaxial pattern 150E2 are formed. Also, unless otherwise indicated, the components in the example embodiment may be understood with reference to the description of the same components of the circuit device 100B illustrated in FIGS. 3A and 3B.

Circuit device 100F in the example embodiment may be configured as a PN diode. The semiconductor stack body SL may have a first conductivity-type impurity region W1. For example, the first conductivity-type impurity region W1 may be configured as an N-type well. The first conductivity-type epitaxial pattern 150E1 and the second conductivity-type epitaxial pattern 150E2 may be formed in the first conductivity-type impurity region W1. The second conductivity-type epitaxial pattern 150E2 may be disposed in the recess formed in the lower surface of the semiconductor stack body. The first conductivity-type epitaxial pattern 150E1 may be disposed in the through-hole penetrating through the semiconductor stack body SL. The first conductivity-type epitaxial pattern 150E1 may be disposed on a level higher than a level of the second conductivity-type epitaxial pattern 150E2 in the through-hole.

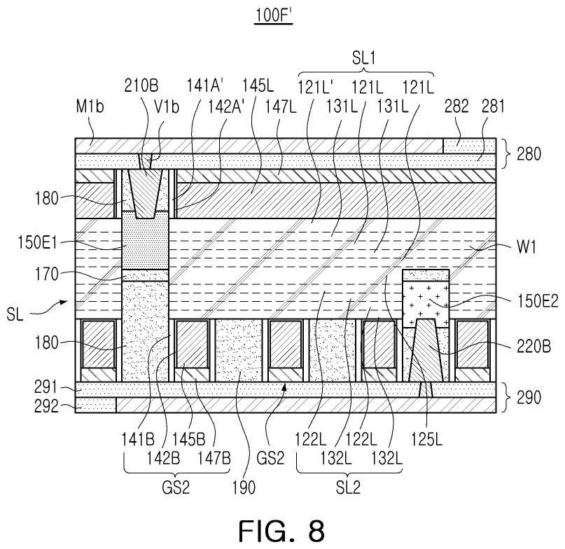

FIG. 8 is a lateral cross-sectional diagram illustrating a semiconductor device (e.g., the circuit device) according to an example embodiment.

Referring to FIG. 8, the circuit device 100F′ in the example embodiment may be similar to the circuit device 100F shown in FIGS. 7A and 7B other than the configuration in which the conductivity-type of the impurity region in which a single semiconductor stack body SL is provided is changed. Also, unless otherwise indicated, the components in the example embodiment may be understood with reference to the description of the same components of the circuit device 100F illustrated in FIGS. 7A and 7B.

The circuit device 100F′ in the example embodiment may be configured as a PN diode. Differently from the aforementioned example embodiment, the semiconductor stack body SL may have a second conductivity-type impurity region W2. For example, the first conductivity-type impurity region W2 may be configured as a P-type well. The first conductivity-type epitaxial pattern 150E1 and the second conductivity-type epitaxial pattern 150E2 may be formed in the second conductivity-type impurity region W2. Similarly to the aforementioned example embodiment, the second conductivity-type epitaxial pattern 150E2 may be disposed in a recess formed in the lower surface of the semiconductor stack body. The first conductivity-type epitaxial pattern 150E1 may be disposed in the through-hole penetrating through the semiconductor stack body SL.

The circuit device in the example embodiment may be implemented as a capacitor. For example, the circuit device may be implemented as a capacitor (e.g., N-type capacitor) using a specific conductivity-type semiconductor as a capacitance material.

FIGS. 9A and 9B are a plan diagram and a lateral cross-sectional diagram respectively illustrating a semiconductor device (e.g., capacitor) according to an example embodiment.

Referring to FIGS. 9A and 9B, the circuit device 100G in the example embodiment may be similar to the circuit device 100B illustrated in FIGS. 3A and 3B other than the configuration in which the third upper contacts 210C connected to the electrode material layer 145L disposed on the semiconductor stack body SL are included, and the configuration in which the other interconnection lines M1b and M1c to implement a capacitor are included. Also, unless otherwise indicated, the components in the example embodiment may be understood with reference to the description of the same components of the circuit device 100B illustrated in FIGS. 3A and 3B.

The circuit device 100G in the example embodiment may be configured as a capacitor device, and may include a first conductivity-type impurity region W1 of semiconductor stack body SL, and a plurality of first conductivity-type epitaxial patterns 150E1 each disposed in the plurality of through-holes and connected to the semiconductor stack body SL (particularly, the upper stack body SL1). As described above, the first conductivity-type impurity region W1 may be provided as a capacitance structure.

As described above, the plurality of second upper contacts 210B may be connected to the first conductivity-type epitaxial pattern 150E2 through the first gap-fill insulating layer. The circuit device 100F in the example embodiment may include a plurality of third upper contacts 210C penetrating through the capping insulating layer 147L and connected to the electrode material layer 145L, along with the plurality of second upper contacts 210B. The plurality of third upper contacts 210C may be electrically connected to the first conductivity-type impurity region W1 through the electrode material layer 145L. Also, the circuit device 100F in the example embodiment may not include the first gate insulating layer 142A′, differently from the example embodiment illustrated in FIG. 3A.

Referring to FIG. 9A, the plurality of second upper contacts 210B may be connected to the second upper interconnection line M2 through the plurality of metal vias V1b, and the plurality of third upper contacts 210C may be connected to the third upper interconnection line M3 through the plurality of metal vias V1c.

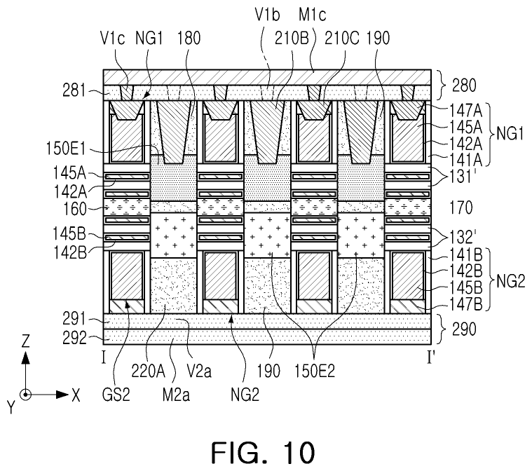

FIG. 10 is a lateral cross-sectional diagram illustrating a semiconductor device (e.g., capacitor) according to an example embodiment.

Referring to FIG. 10, the circuit device 100G in the example embodiment may be configured as a capacitor device and may include a device having a structure similar to that of the logic device 100A described in FIG. 2A. However, in the example embodiment, the structures corresponding to the first and second gate structures may be provided as first and second inactive gate structures NG1 and NG2, respectively, which are not used as gates of activated transistors. However, the first inactive gate structure NG1 may be provided as an electrode structure on one side of the capacitor. Also, the first conductivity-type impurity region W1 of the semiconductor stack body SL, and the plurality of first conductivity-type epitaxial patterns 150E1 disposed in the plurality of through-holes and connected to the semiconductor stack body SL (particularly, the upper stack body SL1) may be included.

The circuit device 100G in the example embodiment may include first semiconductor patterns 131 and a plurality of first conductivity-type epitaxial patterns 150E1, which work as a capacitance material.

The circuit device 100G in the example embodiment may include a plurality of third upper contacts 210C connected to the first gate electrode 145A through the first gate capping layer 147A, along with the upper contacts 210B. The plurality of third upper contacts 210C may be electrically connected to the first semiconductor patterns 131 through the first gate electrode 145A.

Similarly to the aforementioned example embodiment, the plurality of second upper contacts 210B may be connected to the second upper interconnection line M2 through the plurality of metal vias V1b, and the plurality of third upper contacts 210C may be connected to the third upper interconnection line M3 through the plurality of metal vias V1c (see FIG. 9A).

FIGS. 11A to 11I are cross-sectional diagrams illustrating a portion of processes of a method of manufacturing a semiconductor device according to an example embodiment. The manufacturing method in the example embodiment may be understood as a process of manufacturing the semiconductor device 100 illustrated in FIG. 1, and each process cross-sectional diagram may include cross-sectional diagrams corresponding to the logic device in FIG. 2A and the circuit device in FIG. 3A, respectively.

Referring to FIG. 11A, a semiconductor stack body SL may be formed on a substrate 101, that is, in first and second device regions A and B.

The substrate 101 may include a semiconductor material, for example, a group IV semiconductor, a group III-V compound semiconductor, or a II-VI compound semiconductor. For example, a group IV semiconductor may include silicon (Si), germanium (Ge), or silicon germanium (SiGe). The substrate 101 may include a bulk wafer, an epitaxial layer, or a silicon on insulator (SOI) layer.

The semiconductor stack body SL may be formed by alternately stacking semiconductor layers of different compositions on the substrate. The semiconductor layers include an intermediate semiconductor layer 125L, first sacrificial layers 121L (also referred to as “first upper semiconductor layer”) stacked alternately on the lower surface of the intermediate semiconductor layer 125L, an upper stack body SL1 (also referred to as “first stack body”) having first semiconductor layers 131L (also referred to as “second upper semiconductor layer”), second sacrificial layers 122L (also called ‘first lower semiconductor layer’) stacked alternately on the lower surface of the intermediate semiconductor layer 125L, and a lower stack body SL2 (also referred to as “second stack body”) having second semiconductor layers 132L (also referred to as “second semiconductor layer”). The semiconductor layers of different compositions may be implemented by differences in germanium composition ratio (e.g., 0 to 60%).

The first semiconductor layers 131L and the second semiconductor layers 132L may be used to configure a channel of logic device 100A. For example, the first semiconductor layers 131L and the second semiconductor layers 132L may include silicon. The first sacrificial layers 121L, the second sacrificial layers 122L, and the intermediate semiconductor layer 125L may be used as selectively removable sacrificial layers, and may include silicon germanium having a relatively high concentration of germanium (e.g., 15% or more). Depending on the process order for removing the sacrificial layers, the first sacrificial layers 121L, the second sacrificial layers 122L, and the intermediate semiconductor layer 125L may also be configured to have different concentrations of germanium. In the example embodiment, in the process of forming the logic device 100A, the intermediate semiconductor layer 125L, which may be removed preferentially, may have a concentration of germanium greater than a concentration of germanium of each of the first sacrificial layers 121L and the second sacrificial layers 122L. Also, the second sacrificial layers 122L may have a greater concentration of germanium than the concentration of germanium of each of the first sacrificial layers 121L. However, an example embodiment thereof is not limited thereto, and the first sacrificial layers 121L and the second sacrificial layers 122L may have the same concentration of germanium.

In some example embodiments, the thickness t1 of the intermediate semiconductor layer 125 may be greater than the thickness of each of the first and second semiconductor layers 121L and 131L or the first and second semiconductor layers 122L and 132L. In some example embodiments, the second stack body SL2 may be arranged such that the second sacrificial layer 122L and the second semiconductor layer 132L may be disposed as at least the lowermost layer (i.e., the layer in contact with the intermediate semiconductor layer 125) and the uppermost layer, respectively, of the second stack body SL2. The first stack body SL1 may be arranged such that the first sacrificial layers 121L′ and 121L may be disposed as at least the lowermost layer and uppermost layer of the first stack body SL1. Here, the thickness t2 of the first sacrificial layer 121L′, which is the lowermost layer, may be larger than the respective thicknesses of the other first sacrificial layers 121L.

Thereafter, referring to FIG. 11B, in the first device region A, the semiconductor stack body SL may be patterned to form a fin-type structure FS, and in the second device region B, desired impurity regions W1 and W2 may be formed in the semiconductor stack body SL.

The process of forming the fin-type structure may be selectively performed only on the first device region A, and during the process of forming the fin-type structure, the second device region B may be covered with a mask (not illustrated). In the first device region A, the fin-type structure FS may extend lengthwise in the first direction (e.g., the X-direction) on the substrate 101 and a plurality of the fin-type structures FS may be formed and arranged in parallel in the second direction (e.g., the Y-direction).

In the second device region B, impurity regions W1 and W2 may be formed in the semiconductor stack body SL to form a circuit device using an ion implantation process. The ion implantation process may be selectively performed only on the second device region B, and the first device region A may be covered with a mask (not illustrated) during the ion implantation process. Similarly to the example illustrated in FIG. 1, on a plan diagram, the semiconductor stack body SL may include a first conductivity-type impurity region W1 and a second conductivity-type impurity region W2 surrounding the first conductivity-type impurity region W1.

Thereafter, referring to FIG. 11C, a plurality of dummy gate structures DG may be formed in the first and second device regions (e.g., first and second device regions A and B).

The plurality of dummy gate structures DG may extend lengthwise in the second direction (e.g., the Y-direction) and may be arranged in parallel in the first direction (e.g., the X-direction). In the example embodiment, the plurality of dummy gate structures DG may be arranged with a first pitch in the first device region A and may be arranged with a second pitch in the second device region. The first pitch and the second pitch may be arranged identically, but an example embodiment thereof is not limited thereto.

The plurality of dummy gate structures DG in the first device region A may be formed to intersect the fin-type structure FS (see FIG. 1), and the plurality of dummy gate structures DG in second device region B may be formed on a flat surface of the semiconductor stack body SL.

In this process, gate spacers 141 may be formed on both sides of the dummy gate structures DG along with the dummy gate structures DS. Each of the dummy gate structures DS may be provided as a sacrificial structure providing a space for forming the gate structures GS to be formed in subsequent processes. The dummy gate structures DS may include dummy material layers 245, and mask pattern layers 247. The dummy material layers 245 may be patterned using the mask pattern layer 247. The dummy material layers 245 may be an insulating layer and a conductive layer, respectively, but in some example embodiments, the dummy material layers 245 may include polysilicon. The mask pattern layer 247 may include silicon oxide and/or silicon nitride. However, an example embodiment thereof is not limited thereto, and dummy material layers 245 may include a plurality of different material layers. For example, the dummy material layers 245 may further include an insulating film such as silicon oxide below polysilicon.

The gate spacers 141 may be formed on both sidewalls of the dummy gate structures DS. The gate spacers 141 may be formed by forming a film of uniform thickness along an upper surface and a side surface of the substrate on which the dummy gate structures DS are formed, and performing anisotropically etching. The gate spacers 141 may be formed of a low-x material and may include, for example, at least one of SiO, SiN, SiCN, SiOC, SiON, and SiOCN.

Thereafter, referring to FIG. 11D, in the first device region, portions of the fin-type structure FS between the dummy gate structures DS may be removed, thereby forming the first recess RS1.

In some embodiments, the process may be selectively performed only on the first device region A, and during this process, the second device region B may be covered with a mask (not illustrated).

In the example embodiment, the first recess RS1 may be formed sufficiently deeply in the substrate 101. In this process, the process may be performed by removing exposed regions of the fin-type structure FS using the dummy gate structures DS and the gate spacers 141 as masks. Through this process, the first and second semiconductor patterns 131 and 132 may have the desired channel length in the first direction (e.g., the X-direction). The side portions of the first semiconductor patterns 131 exposed by the first recess RS1 may be provided as a region for forming the first source/drain pattern, and the side portions of the second semiconductor patterns 132 may be provided as a region for forming the second source/drain pattern.

Thereafter, referring to FIG. 11E, in the second device region B, second and third recesses RS2 and RS3 may be formed in the semiconductor stack body SL.

This process may be selectively performed only on the second device region B, and during this process, the first device region A may be covered with a mask (not illustrated).

In the example embodiment, the second recess RS2 may be formed to a depth penetrating through the second stack body SL2, and the third recess RS3 may be formed sufficiently deeply into the substrate 101, similarly to the first recess RS1. This process may also be performed by removing exposed regions of the semiconductor stack body SL using the dummy gate structures DS and the gate spacers 141 as masks. The second recess RS2 may be provided as a space for the second conductivity-type epitaxial pattern, and the third recess RS3 may be provided as a space for the first conductivity-type epitaxial pattern. The third recess RS3 may be provided as a through-hole after removing the substrate.

Thereafter, referring to FIG. 11F, in the first and second device regions A and B, the first and second gap-fill insulating layers 180′ and 190′ may be formed in the spaces between the dummy gate structure DG to fill the first to third recess RS1, RS2, and RS3, and thereafter, the first gap-fill insulating layer 180′ of the first recess RS1 and the third recess RS3 may be selectively recessed, and a blocking insulating layer 260 may be formed.

For ease of description, the portion filled with the same insulating material portion may be divided into a first gap-fill insulating layer 180′ and a second gap-fill insulating layer 190′. The insulating material portion filled in the first recess RS1 and third recess RS3 may be referred to as the first gap-fill insulating layer 180, and the insulating material portion filled in the spaces between the second recess and dummy gate structure DG may be referred to as a second gap-fill insulating layer 190.

The process of forming of the first gap-fill insulating layer 180′ and the second gap-fill insulating layer 190′ may be obtained by depositing a first insulating material to fill the spaces between the dummy gate structures DS, and planarizing such as chemical mechanical polishing (CMP). For example, the first gap-fill insulating layer 180′ and the second gap-fill insulating layer 190′ may be silicon oxide such as spin on hardmask (SOH). The process of optionally recessing the first gap-fill insulating layer 180′ may be performed by a process such as etch-back. The first gap-fill insulating layer 180′ of the first recess RS1 may be formed to have an upper surface level covering at least the side surfaces of the first semiconductor pattern 131. The first gap-fill insulating layer 180′ of the third recess RS3 may also have the same level as that of the first gap-fill insulating layer 180′ of the first recess RS1. In the example embodiment, an upper surface level of the recessed first gap-fill insulating layers 180′ may be formed to overlap the intermediate semiconductor layer 125 in the horizontal direction.

Thereafter, the blocking insulating layer 260 may conformally form the second insulating material throughout the entire region. Specifically, the second insulating material may be formed on the sidewalls of the dummy gate structures DS, as well as the upper surface of the dummy gate structures DS and the upper surface of the first gap-fill insulating layer 180′. The second insulating material may include a dielectric material that inhibits epitaxial growth. For example, the second insulating material may include silicon nitride (SiN), silicon oxynitride (SiON), or silicon carbonitride (SiCN).

Thereafter, referring to FIG. 11G, the first gap-fill insulating layer 180′ may be exposed on a bottom surface of the first and third recess RS1 and RS3, and the exposed first gap-fill insulating layer 180′ may be further recessed, thereby exposing the first semiconductor patterns 131.

The process of exposing the first gap-fill insulating layer 180′ may be performed by an anisotropic etching process such as dry etching. Specifically, through an anisotropic etching process, portions disposed on the upper surfaces of the dummy gate structures DS and the second gap-fill insulating layer 190′ and the upper surfaces of the first gap-fill insulating layer 180′ may be removed from the blocking insulating layer 260. Accordingly, a blocking insulating layer 260 may remain on the exposed sidewall portions of the dummy gate structure DS. The blocking insulating layer 260 may be provided to cover the sidewall portion of the dummy gate structure DS including the side surface of the second semiconductor pattern layers 132.

Thereafter, the first gap-fill insulating layer 180′ may be partially recessed such that the side surface of the first semiconductor patterns 131 may be opened. Thereafter, the desired first source/drain patterns 150A may be formed by growing the epitaxial from the side surfaces of the first semiconductor patterns 131. During the epitaxial growth process, the epitaxial layer growth may be suppressed in the portion in which the blocking insulating layer 260 is formed. Simultaneously with the process of forming the first source/drain patterns 150A, the first conductivity-type epitaxial pattern 150E1 may be formed in the third recess RS3. The first conductivity-type epitaxial pattern 150E1 may be grown from the side surface of the first semiconductor layers 131L, which is opened, through an additional recess process in the third recess RS3. As such, in the example embodiment, the first source/drain patterns 150A and the first conductivity-type epitaxial pattern 150E1 may be formed by the same epitaxial growth process. The first source/drain patterns 150A and the first conductivity-type epitaxial pattern 150E1 may include the same conductivity-type semiconductor material and may be disposed on the same level.

Thereafter, referring to FIG. 11H, the blocking insulating layer 260 may be removed, a third insulating material may be deposited, and a selective etch-back process may be performed such that the first and second recesses RS1′ and RS2′ may be formed again. In this process, an isolation insulating layer 170 may be formed.

This process may be performed by a process of depositing the third insulating material to fill the first and third recesses RS1 and RS3, and a planarization process such as CMP. The third insulating material may be a material similar to the first insulating material. For example, the material may be a silicon oxide such as SOH. Thereafter, an isolation insulating layer 170 may be formed in the first and second recesses RS1′, RS2′ by performing a process such as selective etch-back to form the first and second recesses RS1′ and RS2′. The isolation insulating layer 170 may cover the first source/drain pattern 150A in the first recess RS1′ and the bottom surface of the second recess RS2′. Also, in the process of forming the isolation insulating layer 170, the space above the first conductivity-type epitaxial pattern 150E1 of the third recess may also be filled.

Thereafter, referring to FIG. 11I, in the first and second device regions A and B, a second source/drain pattern 150B and second conductivity-type epitaxial patterns 150E2a and 150E2b may be formed simultaneously.

In the first recess RS1′, the second source/drain pattern 150B may be formed from the side surface of the exposed second semiconductor patterns 132, and in the second recesses RS2′, the second conductivity-type epitaxial patterns 150E2a and 150E2b may be formed from the side surface of the exposed second semiconductor layers 132L. As such, in the example embodiment, the second source/drain patterns 150B and the second conductivity-type epitaxial patterns 150E2a and 150E2b may be formed by the same epitaxial growth process. The second source/drain patterns 150B and the second conductivity-type epitaxial patterns 150E2a and 150E2a may include the same conductivity-type semiconductor material.

FIGS. 12A to 12G are cross-sectional diagrams illustrating the other portion of processes of a method of manufacturing a semiconductor device according to an example embodiment.

Referring to FIG. 12A, a process of partially removing the dummy gate structure DG may be performed. In the example illustrated in FIG. 11I, an insulating layer may be formed to fill the space between the dummy gate structures DG, and a CMP process may be performed to remove up to the mask pattern layer 247 (e.g., up to the PL line). In the dummy gate structure DG, the dummy material layer 245 may be exposed.

Thereafter, referring to FIG. 12B, in the first device region A, the dummy material layer 145 may be removed, and the intermediate semiconductor layer 125 may be removed by applying a selective etching process through the removed space DH1. Accordingly, the first space O1 from which the intermediate semiconductor layer 125 is removed may be obtained. Thereafter, referring to FIG. 12C, in the first device region A, an insulating material may be filled in the first space O1 to form an insulating isolation pattern 160.

Thereafter, referring to FIG. 12D, a space DH1 between the gap-fill insulating layers 190 may be formed by selectively removing the dummy material layer 145 from the second device region B, and thereafter, a second space O2 between second semiconductor patterns 132 may be formed by selectively removing the second sacrificial patterns 122 from the first device region A. Even when the dummy material layer 245 is removed from the second device region B and the semiconductor stack body SL is exposed, differently from the first device region, the component may not have a fin-type structure, such that only the upper surface of the semiconductor stack body SL, that is, the second semiconductor layer 132L, may be exposed. Accordingly, even in the process of selectively removing the second sacrificial patterns 122 in the first device region A, the semiconductor stack body SL in the second device region B may not be etched.

Thereafter, referring to FIG. 12E, the second gate structure GS2 may be formed, and the first to third lower contacts 220A, 220B, and 220C may be formed.

The process of forming the second gate structure GS2 may be performed by conformally forming the second gate insulating layer 142B to surround the exposed second semiconductor patterns 132. Thereafter, the second gate electrodes 145B may be formed to be buried in the spaces DH1 and DH2 from which the dummy material layer are removed, and may be recessed to a predetermined depth. Thereafter, the second gate structure GS2 may be formed in the first device region A by forming a second gate capping layer 147B on the second gate electrodes 145B and performing a CMP process. In this same process, an inactive gate structure NG having the same structure as the second gate structure GS2 may be formed in the second device region B. In the first device region A, the first lower contact 220A may penetrate through the second gap-fill insulating layer 190 and may be connected to the second source/drain pattern 150B, and in the second device region B, the second and third lower contacts 220B and 220C may penetrate through the second gap-fill insulating layer 190 and may be connected to the second conductivity-type epitaxial pattern 150E2a and 150E2b, respectively. In some example embodiments, the second interconnection structure 290 described in FIGS. 2A and 3A may be further formed.

Thereafter, referring to FIG. 12F, the substrate 101 may be removed, and the first sacrificial patterns 121 may be selectively removed, thereby forming a third space O3 between the first semiconductor patterns 131.

The removal of substrate 101 may be performed by a wet etching process. During the wet etching process, the first semiconductor patterns 131 provided as a channel may be protected by the first sacrificial pattern 121, which is an uppermost portion having a relatively great thickness.

After the substrate 101 is removed, a first open region OP1 may be provided to the first device region A and a second open region OP2 may be provided to the second device region B. In some example embodiments, the first and second open regions may be formed, and the first gate spacer 141A may be formed. The space material may be conformally deposited, and an anisotropic etching process may be applied to remain only on the sidewall of the first gap-fill insulating layer 190.

Thereafter, the first sacrificial patterns 121 may be selectively removed from the first device region A such that a third space O3 may be formed between the first semiconductor patterns 131. In this process, the first sacrificial pattern 121, which is an uppermost portion having a relatively great thickness, may also be removed. Even when the substrate 101 is removed from the second device region B and the semiconductor stack body SL is exposed, differently from the first device region A, the component may not have a fin-type structure, such that only the upper surface of the semiconductor stack body SL, that is, the uppermost first sacrificial layer 121L, may be exposed, and a portion or the entirety thereof may be removed. After the uppermost first sacrificial layer 121L is removed, the component may be protected by the second-uppermost first semiconductor layer 131L. Accordingly, even in the process of selectively removing the first sacrificial patterns 121 in the first device region A, the semiconductor stack body SL in the second device region B may not be further etched.

Thereafter, referring to FIG. 12G, the first gate structure GS1 may be formed in the first device region A, and simultaneously, the electrode material layer 145L and the capping insulating layer 147L may be formed in the second device region B. Thereafter, the first and second upper contacts 210A and 210B may be formed.

In the first device region A, the process of forming the first gate structure GS1 may be performed as a process of conformally forming the first gate insulating layer 142A to surround the exposed first semiconductor patterns 131. Thereafter, the first gate electrodes 145A may be formed to be buried in the space OP1 from which the substrate 101 is removed, and may be recessed to a predetermined depth. Thereafter, the second gate structure GS2 may be formed in first device region A by forming a second gate capping layer 147B on the second gate electrodes 145B and performing a CMP process. In this same process, in the second device region B, layers identical to the second gate structure GS2 may be formed in the space OP2 in which the substrate 101 has been removed. For example, the first gate insulating layer 142A may be formed on the internal sidewall of the first gate spacer 141A. Subsequently, in the process of forming the first gate structure, an electrode material layer 145L and a capping insulating layer 147L may be formed sequentially in the second device region. The electrode material layer 145L may include the same electrode material as that of the first gate electrode 145A, and the capping insulating layer 147L may include the same insulating material as that of the first gate capping layer 147A. In the first device region A, the first upper contact 210A may penetrate through the first gap-fill insulating layer 180 and may be connected to the first source/drain pattern 150A, and in the second device region B, the second upper contact 210B may penetrate through the first gap-fill insulating layer 180 and may be connected to the first conductivity-type epitaxial pattern 150E1. In some example embodiments, the first interconnection structure 280 described in FIGS. 2A and 3A may be further formed.

According to the aforementioned example embodiments, in a semiconductor device without a bulk substrate, various circuit devices may be implemented to form a peripheral circuit using the semiconductor stack body to form a channel layer and the epitaxial pattern corresponding to the source/drain pattern.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a semiconductor stack body having a first surface and a second surface opposite to each other, including semiconductor layers having different compositions stacked therein, and including at least one of a first conductivity-type impurity region and a second conductivity-type impurity region, wherein the semiconductor stack body has a recess formed in the second surface and a through-hole penetrating through the semiconductor stack body;
a plurality of inactive gate structures disposed and spaced apart from each other on the second surface of the semiconductor stack body, wherein each of the recess and the through-hole is disposed between the plurality of inactive gate structures;
a first conductivity-type epitaxial pattern disposed in the through-hole and connected to the semiconductor stack body;
a second conductivity-type epitaxial pattern disposed in the recess and connected to the semiconductor stack body;
a first gap-fill insulating layer disposed on the first conductivity-type epitaxial pattern in the through-hole adjacent to the second surface of the semiconductor stack body;
a second gap-fill insulating layer disposed between the plurality of inactive gate structures on the second surface of the semiconductor stack body;
a first contact penetrating through the first gap-fill insulating layer and connected to the first conductivity-type epitaxial pattern; and
a second contact penetrating through the second gap-fill insulating layer and connected to the second conductivity-type epitaxial pattern.

2. The semiconductor device of claim 1, wherein the first conductivity-type epitaxial pattern is disposed on a level higher than a level of the second conductivity-type epitaxial pattern in the through-hole.

3. The semiconductor device of claim 1, wherein the semiconductor stack body includes the first conductivity-type impurity region and the second conductivity-type impurity region arranged in a horizontal direction.

4. The semiconductor device of claim 3,
wherein the second conductivity-type epitaxial pattern includes two second conductivity-type epitaxial patterns, and the recess includes a first recess in the first conductivity-type impurity region, and a second recess in the second conductivity-type impurity region,
wherein the two second conductivity-type epitaxial patterns are disposed in the first and second recesses, respectively, and
wherein the first conductivity-type epitaxial pattern is disposed in one of the first and second conductivity-type impurity regions between the two second conductivity-type epitaxial patterns.

5. The semiconductor device of claim 4, wherein the semiconductor stack body includes an isolation hole between the first conductivity-type epitaxial pattern and the second conductivity-type epitaxial pattern disposed in the same conductivity-type impurity region among the two second conductivity-type epitaxial patterns.

6. The semiconductor device of claim 3,
wherein the first conductivity-type epitaxial pattern includes two first conductivity-type epitaxial patterns, and the through-hole includes a first through-hole in the first conductivity-type impurity region, and a second through-hole in the second conductivity-type impurity region,
wherein the two first conductivity-type epitaxial patterns are disposed in the first and second through-holes, respectively, and
wherein the second conductivity-type epitaxial pattern is disposed in one of the first and second conductivity-type impurity regions between the two first conductivity-type epitaxial patterns.

7. The semiconductor device of claim 1,
wherein the semiconductor stack body includes one impurity region of the first and second conductivity-type impurity regions, and
wherein the first conductivity-type epitaxial pattern and the second conductivity-type epitaxial pattern are spaced apart from each other and disposed in the one impurity region.

8. The semiconductor device of claim 1, further comprising:
an electrode material layer disposed on the first surface of the semiconductor stack body, and
an insulating capping layer disposed on the electrode material layer.

9. A semiconductor device, comprising:
a semiconductor stack body including an upper stack body having an intermediate semiconductor layer, and first upper semiconductor layers and second upper semiconductor layers stacked alternately on an upper surface of the intermediate semiconductor layer, a lower stack body having first lower semiconductor layers and second lower semiconductor layers stacked alternately on a lower surface of the intermediate semiconductor layer, and a first conductivity-type impurity region and a second conductivity-type impurity region disposed horizontally;
a plurality of inactive gate structures arranged at a pitch on a lower surface of the semiconductor stack body;
at least one recess disposed between at least one pair of adjacent inactive gate structures among the plurality of inactive gate structures and penetrating through the lower stack body from a lower surface of the semiconductor stack body;
at least one through-hole disposed between at least one pair of adjacent inactive gate structures among the plurality of inactive gate structures and penetrating through the semiconductor stack body;
at least one first conductivity-type epitaxial pattern disposed in the at least one through-hole and connected to the upper stack body of the semiconductor stack body; and
at least one second conductivity-type epitaxial pattern disposed in the at least one recess and connected to the lower stack body of the semiconductor stack body.

10. The semiconductor device of claim 9, wherein the first upper semiconductor layers are provided as at least an uppermost first upper semiconductor layer and a lowermost first upper semiconductor layer of the upper stack body, respectively, and the uppermost first upper semiconductor layer, which is the uppermost layer of the first upper semiconductor layers, has a thickness greater than a thickness of other first upper semiconductor layers.

11. The semiconductor device of claim 10, further comprising:
an electrode material layer disposed on the upper surface of the semiconductor stack body; and
an insulating capping layer covering the electrode material layer.

12. The semiconductor device of claim 9, wherein the intermediate semiconductor layer has a thickness greater than a thickness of each of the first and second upper semiconductor layers or the first and second lower semiconductor layers.

13. The semiconductor device of claim 9,
wherein the second upper semiconductor layers and the second lower semiconductor layers include silicon, and
wherein the first upper semiconductor layers, the first lower semiconductor layers, and the intermediate semiconductor layer include silicon germanium.

14. The semiconductor device of claim 13, wherein the intermediate semiconductor layer has a concentration of germanium greater than a concentration of germanium of each of the first upper semiconductor layers and the first lower semiconductor layers.

15. The semiconductor device of claim 13, wherein the first upper semiconductor layers and the first lower semiconductor layers have a same concentration of germanium.

16. A semiconductor device, comprising:
a first device region and a second device region disposed horizontally,
wherein the first device region includes:
a channel structure including an insulating isolation pattern, first semiconductor patterns vertically stacked and spaced apart from each other on an upper surface of the insulating isolation pattern, and second semiconductor patterns vertically stacked and spaced apart from each other on a lower surface of the insulating isolation pattern;
a pair of first source/drain patterns disposed on both sides of the channel structure in a first direction and connected to both sides of the first semiconductor patterns, respectively;
a pair of second source/drain patterns disposed on both sides of the channel structure and connected to both sides of the second semiconductor patterns, respectively;
a first gate structure extending in a second direction intersecting the first direction and surrounding the first semiconductor patterns; and
a second gate structure intersecting a lower surface of the channel structure, extending in the second direction and surrounding the second semiconductor patterns, and
wherein the second device region includes:
a semiconductor stack body disposed on a level corresponding to a level of the channel structure, and including an upper stack body having first upper semiconductor layers and second upper semiconductor layers alternately stacked on an upper surface of an intermediate semiconductor layer, and a lower stack body having first lower semiconductor layers and second lower semiconductor layers stacked alternately on a lower surface of the intermediate semiconductor layer, wherein the semiconductor stack body includes a first conductivity-type impurity region and a second conductivity-type impurity region disposed in a horizontal direction;
a plurality of inactive gate structures arranged on a lower surface of the semiconductor stack body;
a first conductivity-type epitaxial pattern disposed in a through-hole penetrating through the semiconductor stack body between adjacent inactive gate structures among the plurality of inactive gate structures, and connected to the upper stack body; and
a second conductivity-type epitaxial pattern disposed in a recess formed on a lower surface of the semiconductor stack body between other adjacent inactive gate structures among the plurality of inactive gate structures, and connected to the lower stack body.

17. The semiconductor device of claim 16,
wherein the first conductivity-type epitaxial pattern includes a same material as a material of the pair of first source/drain patterns, and
wherein the second conductivity-type epitaxial pattern includes a same material as a material of the pair of second source/drain patterns.

18. The semiconductor device of claim 16, wherein the semiconductor stack body has a thickness corresponding to a height of the channel structure.

19. The semiconductor device of claim 16,
wherein the first upper semiconductor layers are provided as at least an uppermost first upper semiconductor layer and a lowermost first upper semiconductor layer of the upper stack body, respectively, and the uppermost first upper semiconductor layer, which is the uppermost layer of the first upper semiconductor layers, has a thickness greater than a thickness of the other first upper semiconductor layers, and
wherein an upper surface of the semiconductor stack body has a level higher than a level of an upper surface of the channel structure by a thickness of the uppermost first upper semiconductor layer.

20. The semiconductor device of claim 16,
wherein the second device region further includes an electrode material layer disposed on the upper surface of the semiconductor stack body, and an insulating capping layer covering the electrode material layer, and
wherein the electrode material layer includes the same material as a material of a gate electrode of the first gate structure.
